(19) United States
(12) Patent Application Publication
(10) Pub. No.: US 2026/0221107 A1
(43) Pub. Date: Jul. 30, 2026

(54) Display Device

(71) Applicant: LG Display Co., Ltd., Seoul (KR)

(72) Inventors: Hwi Deuk Lee, Paju-si (KR); Ye Seul Han, Paju-si (KR); Eui Tae Kim, Paju-si (KR); Kwang Hyun Choi, Paju-si (KR); Soon Hwan Hong, Paju-si (KR)

(21) Appl. No.: 19/453,957

(22) Filed: Jan. 20, 2026

(30) Foreign Application Priority Data
Jan. 24, 2025 (KR) 10-2025-0011977

(51) Int. Cl. G09G 3/3266; G09G 3/325; G09G 3/3291; H10K 59/123; H10K 59/124

(52) U.S. Cl. CPC G09G 3/3266; G09G 3/325; G09G 3/3291; H10K 59/123; H10K 59/124; G09G 2300/0408; G09G 2300/0426; G09G 2300/0452; G09G 2300/0819; G09G 2300/0842; G09G 2310/0297; G09G 2310/08; G09G 2320/0209; G09G 2320/045

(57) ABSTRACT

A display device includes a display panel having an active area and a non-active area. The display panel includes pixel areas with subpixels in the active area and circuit areas in which scan circuits supplying scan signals to the subpixels are located, the pixel areas and the circuit areas being alternately disposed. The display device further includes an inverter circuit in the non-active area and configured to receive a clock signal supplied to the scan circuits, invert the clock signal, and output an inverted clock signal, a clock line to which the clock signal is applied and which extends along the circuit areas and is connected to the scan circuits, and an inverted clock line to which the inverted clock signal is applied and which extends along the circuit areas from the inverter circuit. The inverted clock line is adjacent to the clock line and extends in the same direction.

### CROSS-REFERENCE TO RELATED APPLICATION

The present application claims the priority to Republic of Korea Patent Application No. 10-2025-0011977, filed on Jan. 24, 2025, which is hereby incorporated by reference in its entirety.

### BACKGROUND

### Field

The present disclosure relates to a display device.

### Discussion of Related Art

As the information society develops, the demand for display devices for displaying images is increasing in various forms.

Organic light-emitting display devices, one of various types of display devices, are widely used because they have the advantages of low power consumption and being small, lightweight, and thin. Recently, electroluminescent display devices in a gate-in-panel (GIP) structure in which scan circuits that generate scan signals to be supplied to gate electrodes of switching transistors included in pixels are directly formed on both sides of an active area have been widely used.

However, in order to achieve a narrow bezel of display devices, a gate driver in active area (GIA) structure in which scan circuits are distributed within an active area has recently been developed.

However, the GIA structure has a problem in that scan circuits need to be disposed within a very narrow space within the active area and is located directly adjacent to pixels, and thus a clock signal supplied to the scan circuits causes coupling with data lines of the pixels, which deteriorates the image quality.

### SUMMARY

Accordingly, the present disclosure is directed to a display device that substantially obviates one or more problems due to limitations and disadvantages of the related art.

An object of the present disclosure is to provide a display device for reducing signal interference such as coupling that may occur due to clock lines disposed in a circuit area.

Additional advantages, objects, and features of the present disclosure will be set forth in part in the description which follows and in part will become apparent to those having ordinary skill in the art upon examination of the following or may be learned from practice of the present disclosure. The objectives and other advantages of the present disclosure may be realized and attained by the structure particularly pointed out in the written description and claims hereof as well as the appended drawings.

To achieve these objects and other advantages and in accordance with the purpose of the present disclosure, as embodied and broadly described herein, a display panel having an active area and a non-active area, and including, a plurality of pixel areas located within the active area and in which a plurality of subpixels are positioned and a plurality of circuit areas alternately disposed with the plurality of pixel areas within the active area and in which scan circuits supplying scan signals to the plurality of subpixels are located, an inverter circuit located in the non-active area and configured to receive a clock signal supplied to the scan circuits, invert the received clock signal, and output an inverted clock signal, a clock line to which the clock signal is applied and which extends along the circuit areas and is connected to the scan circuits, and an inverted clock line to which the inverted clock signal is applied and which extends along the circuit areas from the inverter circuit, wherein the inverted clock line is adjacent to the clock line and extends in the same direction.

The inverter circuit may include a first inverter transistor and a second inverter transistor, the first inverter transistor may include a gate electrode connected to the clock line, a first electrode to which a gate high voltage is applied, and a second electrode connected to the inverted clock line, the second inverter transistor may include a gate electrode connected to the clock line, a first electrode to which a gate low voltage is applied, and a second electrode connected to the inverted clock line, the first inverter transistor may be a PMOS transistor, and the second inverter transistor may be an NMOS transistor.

The inverter circuit may receive the clock signal having the gate high voltage, output the inverted clock signal having the gate low voltage, and the inverter circuit receive the clock signal having the gate low voltage, and output the inverted clock signal having the gate high voltage.

Each of the plurality of subpixels may include a driving transistor located in the pixel area and electrically connected to a light-emitting element, and a switching transistor located in the pixel area and connected to the driving transistor, and the clock line may be located on an insulating layer on which a source electrode and a drain electrode of each of the driving transistor and the switching transistor are located.

The inverted clock line may extend parallel to the clock line while maintaining a predetermined distance from the clock line.

The inverted clock line may be located on a different layer from a layer on which the clock line is located within the circuit area.

The inverted clock line may be located on, an insulating layer on which a metal layer is positioned, the metal layer is positioned below and overlapped with a semiconductor layer of the driving transistor, an insulating layer on which a metal layer is positioned, the metal layer is positioned below and overlapped with a semiconductor layer of the switching transistor, or an insulating layer on which an electrode plate of a storage capacitor connected to the driving transistor is positioned.

The inverted clock line and the clock line may be positioned on the same layer within the circuit area and spaced apart from each other.

The inverted clock line and the clock line may be spaced apart from each other on the insulating layer.

The inverted clock line may be positioned on and spaced apart from both sides of the clock line.

The plurality of circuit areas may include first and second circuit areas, the plurality of pixel areas may include first and second pixel areas alternately positioned with the first and second circuit areas, each of the first and second pixel areas may include first, second and third subpixel areas sequentially arranged in a direction away from each of the first and second circuit areas, and first, second and third subpixels and first, second and third data lines connected to the first, second and third subpixels may be disposed in the first, second and third subpixel areas.

A plurality of constant voltage lines may be disposed at both edges of each of the first and second circuit areas, and the clock line may be disposed between the plurality of constant voltage lines.

The first circuit area may include an open area on which the plurality of constant voltage lines is not positioned and the clock line faces the first pixel area, and the second circuit area may not include the open area.

A line electrically connected to the first subpixel and having a constant voltage may be disposed between the first data line and the first circuit area and be disposed in the first subpixel area of the first pixel area directly adjacent to the open area.

The first data line disposed in the first subpixel area of each of the first and second pixel areas may be positioned on one side of the first subpixel farther away from the first and second circuit areas, and the third data line disposed in the third subpixel area of each of the first and second pixel areas may be positioned on the other side of the third subpixel farther away from the first and second circuit areas.

The second data line may be disposed adjacent to the first data line or the third data line, and a shield line to which a constant voltage is applied may be disposed between the second data line and one of the first data line and the third data line, which is adjacent to the second data line.

The first, second, and third data lines of the first pixel area and the first, second, and third data lines of the second pixel area may be disposed symmetrically with respect to the second circuit area.

Each of the first, second, and third data lines of the second pixel area may be disposed on one side or the other side of each of the first, second, and third subpixels of the second pixel area adjacent to the second circuit area, and each of the first, second, and third data lines of the first pixel area may be disposed on one side or the other side of each of the first, second, and third subpixels of the first pixel area adjacent to the second circuit area.

The display device may further include a multiplexer circuit located in the non-active area adjacent to the first and second pixel areas, receiving a data signal from a data driver, and sequentially outputting a data voltage to the first data line of the first pixel area and the first data line of the second pixel area.

The multiplexer circuit may include a first multiplex transistor having a gate electrode to which a first multiplex signal is applied, a first electrode connected to a data channel of the data driver, and a second electrode connected to the first subpixel located in the first pixel area through the first data line, and a second multiplex transistor having a gate electrode to which a second multiplex signal is applied, a first electrode connected to the data channel, and a second electrode connected to the second subpixel located in the second pixel area through the second data line.

The data signal input to the data channel may include a first data signal applied to the first subpixel through the first data line of the first pixel area and a second data signal applied to the second subpixel through the second data line of the second pixel area.

The first data signal may be output to the first data line of the first pixel area when the first multiplex signal has a turn-on voltage, and the second data signal may be output to the second data line of the second pixel area when the second multiplex signal has the turn-on voltage.

The inverted clock line may be located on the insulating layer and on two sides of and spaced apart from the clock line, and a line width of the inverted clock line is equivalent to or smaller than that of the clock line.

The plurality of constant voltage lines may extend in the same manner as the clock line.

It is to be understood that both the foregoing general description and the following detailed description of the present disclosure are exemplary and explanatory and are intended to provide further explanation of the present disclosure as claimed.

### BRIEF DESCRIPTION OF THE DRAWINGS

The accompanying drawings, which are included to provide a further understanding of the present disclosure and are incorporated in and constitute a part of this application, illustrate embodiment(s) of the present disclosure and together with the description serve to explain the principle of the present disclosure. In the drawings:

FIG. 1 is a block diagram showing an example of a display device according to one or more embodiments of the present disclosure.

FIG. 2 is a diagram illustrating an equivalent circuit and operation timing of a subpixel provided in a pixel illustrated in FIG. 1.

FIGS. 3 to 6 are diagrams for describing a specific operation of the subpixel equivalent circuit illustrated in FIG. 2.

FIG. 7 is a diagram illustrating an arrangement structure of data lines DL of a display panel according to a first embodiment of the present disclosure.

FIG. 8 is a diagram illustrating an arrangement structure of data lines DL of the display panel according to a modified example of the first embodiment of the present disclosure.

FIG. 9 is a diagram showing a multiplexer circuit MX according to one or more embodiments of the present disclosure.

FIG. 10 is a timing diagram illustrating the operation method of the multiplexer circuit MX of FIG. 9.

FIG. 11 is a diagram illustrating an example in which the multiplexer circuit MX of FIG. 9 is applied to a display panel.

FIG. 12 is a diagram illustrating a first example of a structure in which a display panel has an inverter circuit IVC according to a second embodiment of the present disclosure.

FIG. 13 is a diagram illustrating the inverter circuit IVC shown in FIG. 12 in detail.

FIG. 14 is a diagram illustrating a cross section of the display panel according to a first example of the second embodiment of the present disclosure shown in FIG. 12.

FIG. 15 is a diagram illustrating a second example of a structure in which a display panel has an inverter circuit according to the second embodiment of the present disclosure.

FIG. 16 is a diagram illustrating a cross section of the display panel according to a second example of the second embodiment of the present disclosure shown in FIG. 15.

FIG. 17 is a diagram illustrating a third example of a structure in which a display panel has an inverter circuit according to the second embodiment of the present disclosure.

FIG. 18 is a diagram illustrating a cross section of the display panel according to a third example of the second embodiment of the present disclosure shown in FIG. 17.

### DETAILED DESCRIPTION

Hereinafter, preferred embodiments will be described in detail with reference to the attached drawings. Throughout the disclosure, the same reference numerals refer to substantially the same components. In the following description, when it is determined that detailed description of a known function or configuration related to the present disclosure may unnecessarily obscure the subject matter of the present disclosure, the detailed description will be omitted.

Identical drawing numerals refer to identical components. In addition, some of the drawings may be exaggerated for effective description of the thicknesses, ratio, and dimensions of components. The scale of the components illustrated in the drawings is different from the actual scale for the convenience of description and is not limited to the scale illustrated in the drawings.

In the present disclosure, when a component (or region, layer, part, or the like) is referred to as being “on”, “connected to”, or “coupled to” another component, it means that the component can be directly connected/coupled to the other component, or a third component may be disposed therebetween.

“And/or” encompasses all possible combinations of the constituent components.

Although the terms “first”, “second”, etc. may be used to describe various components, the components are not limited by the terms. The terms are only used to distinguish one component from another. For example, without departing from the scope of the present embodiments, a first component may be referred to as a second component, and similarly, the second component may also be referred to as the first component. The singular expression includes the plural expression unless the context clearly indicates otherwise.

The terms “below”, “beneath”, “above”, and “upper” are used to describe the relationship between components depicted in the drawings. These terms are relative concepts and are described based on the directions shown in the drawings. For example, unless “immediately” or “directly” is used, one or more other components may be located between two components. The spatially relative terms “below”, “beneath”, “lower”, “above”, and “upper” may be used to easily describe the relationship between one element or component and another element or components as depicted in the drawings. Thus, for example, “below” and “lower” with respect to a first element may be in the opposite direction to “above” and “upper” with respect to the first element.

Spatially relative terms should be understood as terms that include different directions of elements when used or operated in addition to the directions depicted in the drawings. For example, when an element depicted in a drawing is turned upside down, an element described as “below” or “beneath” another element may be placed “above” the other element. Accordingly, the exemplary term “below” may include both the above and below directions.

It should be understood that the term “include”, “comprise” or “have” is intended to specify the presence of a feature, a number, a step, an operation, a component, a part, or a combination thereof described in the present disclosure, and does not preclude the possibility of the presence or addition of one or more other features, numbers, steps, operations, components, parts, or combinations thereof.

Features of various embodiments of the present disclosure may be partially or wholly combined or joined with each other, and may be technically interconnected and operated in various manners, and the embodiments may be implemented independently of each other or may be implemented in an interconnected relationship.

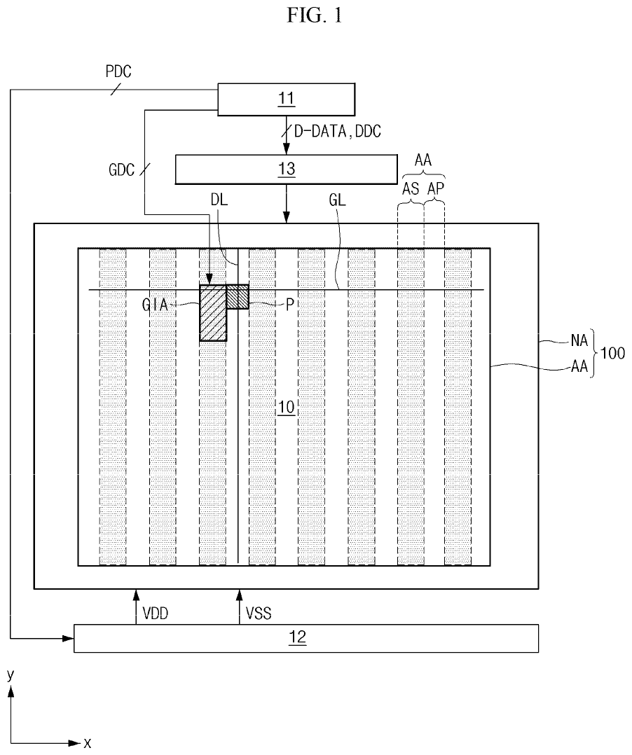

FIG. 1 is a block diagram showing an example of a display device according to one or more embodiments of the present disclosure.

As shown in FIG. 1, a display device according to one or more embodiments of the present disclosure may include a display panel 10, a timing controller 11, a power circuit 12, a data driver 13, a gate driver (e.g., GIA), and a pixel circuit P.

As shown in FIG. 1, the display panel 10 may include an active area AA and a non-active area NA. The non-active area NA may be located along the edge of the display panel 10 and may be located around the active area AA of the display panel 10.

The active area AA may display an image according to an image signal, and the non-active area NA may include a bezel area of the display panel 10 in which no image is displayed.

The active area AA may include a plurality of pixel areas AP and a plurality of circuit areas AS.

The plurality of pixel areas AP and the plurality of circuit areas AS may be arranged alternately in a first direction x (e.g., a horizontal direction), and thus the plurality of circuit areas AS can be arranged between the plurality of pixel areas AP. The plurality of pixel areas AP and the plurality of circuit areas AS may extend in a second direction y (e.g., a vertical direction) intersecting the first direction x.

Hereinafter, an example in which the first direction x is a horizontal direction in which the pixel areas AP and the circuit areas AS are arranged alternately, and the second direction y is a vertical direction in which the pixel areas AP and the circuit areas AS extend will be described.

Subpixels P may be arranged in the plurality of pixel areas AP, and scan circuits GIA may be distributed in the plurality of circuit areas AS. Although one scan circuit GIA and one pixel P are illustrated in FIG. 1 for convenience of understanding, a plurality of pixel circuits P may be disposed in the plurality of pixel areas AP, and a plurality of scan circuits GIA included in a gate driver may be distributed in the plurality of circuit areas AS.

In the active area AA, a plurality of data lines DL extending in the first direction x may intersect a plurality of gate lines GL extending in the second direction y, and pixel circuits P may be disposed at intersections in a matrix form to form a pixel array. In FIG. 1, for convenience of understanding, an example of a case in which one data line DL and one gate line GL intersect each other on one pixel circuit P is illustrated.

The data lines DL may be commonly connected to neighboring pixel circuits P in the second direction y, the gate lines GL may be commonly connected to neighboring pixel circuits P in the first direction x, the data lines DL may be electrically isolated from each other, and the gate lines GL may also be electrically isolated from each other.

For example, each data line DL may be disposed to extend in the first direction x within the pixel area AP, and each gate line GL may be disposed to extend in the second direction y while overlapping the plurality of pixel areas AP and the plurality of circuit areas AS.

The pixel P may express various colors. The pixel P illustrated in FIG. 1 is an example of a unit pixel, and a unit pixel may be configured by grouping a plurality of subpixels. For example, when a group of pixels for color expression is defined as a unit pixel, one unit pixel may include red (R), green (G), and blue (B) subpixels, or may include R, G, B, and white (W) subpixels.

Each subpixel may include a light-emitting element OLED and a driving element that generates a light-emitting current according to a gate-source voltage to drive the light-emitting element OLED.

The light-emitting element OLED may include an anode, a cathode, and an organic compound layer formed therebetween. The organic compound layer may include, but is not limited to, a hole injection layer (HIL), a hole transport layer (HTL), an emission layer (EML), an electron transport layer (ETL), and an electron injection layer (EIL). When a pixel current flows through the light-emitting element OLED, holes passing through the hole transport layer and electrons passing through the electron transport layer move to the emission layer, thereby generating excitons, and as a result, the emission layer may emit visible light. The organic compound layer may be replaced with an inorganic compound layer.

A driving element of each subpixel may include a low-temperature-polysilicon (LTPS) or oxide thin film transistor based on an organic substrate (or plastic substrate), but the present disclosure is not necessarily limited thereto.

The driving elements of the subpixels need to have uniform electrical characteristics (e.g., threshold voltage, electron mobility, etc.) across all pixels, but may differ between pixels P due to process variation and element characteristic variation. The electrical characteristics of the driving elements may change over the display driving time, and the degree of deterioration may differ between pixels P.

To compensate for such variation in the electrical characteristics of the driving elements, an internal compensation method may be applied to the electroluminescent display device. The internal compensation method compensates for variation in the electrical characteristics of the driving elements through an internal compensator included in the pixel circuit P such that the variation does not affect the emission current. The internal compensator may include a plurality of switching elements implemented as thin film transistors and at least one capacitor.

The timing controller 11 may supply digital image data D-DATA transmitted from a host system (not shown) to the data driver 13. The timing controller 11 may receive timing signals such as a vertical synchronization signal, a horizontal synchronization signal, a data enable signal, and a dot clock signal from the host system and generate timing control signals for controlling the operation timing of a panel driving circuit.

The timing control signals may include a gate timing control signal GDC for controlling the operation timing of the gate driver GIA, a data timing control signal DDC for controlling the operation timing of the data driver 13, and a power timing control signal for controlling the operation timing of the power circuit 12.

The host system may be an application processor (AP) in a mobile device, a wearable device, and a virtual/augmented reality device. In addition, the host system may be a main board of a television system, a set-top box, a navigation system, a personal computer, or a home theater system, but is not limited thereto.

The data driver 13 may be connected to the plurality of pixels P through the plurality of data lines DL. The data driver 13 may generate analog voltages required to drive the pixels P and supply the same to the data lines DL.

The data driver 13 may sample and latch digital image data D-DATA input from the timing controller 11 on the basis of the data timing control signal DDC to change the same into parallel data, convert the digital image data D-DATA into analog data voltages according to gamma compensation voltages in a digital-to-analog converter (hereinafter, DAC), and supply the data voltages to the pixels P through the data lines DL. The data voltages may be analog voltage values of different voltage levels and correspond to image grayscales to be expressed in the pixels P.

The data driver 13 may include a plurality of source driver ICs (not shown) connected to the plurality of data lines DL provided in the active area. The source driver IC may include a shift register, a latch, a level shifter, a DAC, and an output buffer.

The gate driver GIA may include scan circuits GIA that generate scan signals, and may further include an EM driver (not shown) that generates an emission control signal, although not shown in FIG. 1.

The pixel circuit P may receive a scan signal and the emission control signal and control emission of the light-emitting element OLED provided in the pixel. In the display device of the present disclosure, the scan circuits GIA and the EM driver may be distributed in the plurality of circuit areas AS, or the scan circuits GIA may be distributed in the plurality of circuit areas AS, and the EM driver may be connected to each gate line GL in the non-active area.

The level shifter may receive the gate timing control signal GDC from the timing controller 11 and convert the voltage of the gate timing signal GDC into a gate on voltage and a gate off voltage, and the level-converted gate timing signal GDC may be input as a clock signal of an EM driver and the scan circuits GIA.

The scan circuits GIA may sequentially supply scan signals to the gate lines GL in synchronization with a data voltage under the control of the timing controller 11.

Each of the scan signals generated by the scan circuits GIA may be generated as a pulse signal that swings between the gate on voltage and the gate off voltage.

The gate on voltage may be set to a voltage greater than the threshold voltage of a transistor, and the gate off voltage may be set to a voltage less than the threshold voltage of the transistor. A transistor provided in the scan circuit GIA may be turned on in response to the gate on voltage and turned off in response to the gate off voltage.

When the transistor provided in the scan circuit GIA is a PMOS transistor, the gate on voltage may be a gate low voltage (VGL) and the gate off voltage may be a gate high voltage (VGH). When the transistor provided in the scan circuit GIA is an NMOS transistor, the gate on voltage may be the gate high voltage (VGH) and the gate off voltage may be the gate low voltage (VGL).

The power circuit 12 may process input power according to the power timing control signal PDC to generate a fixed high-level voltage VDD and a low-level voltage VSS, and supply the same to the pixel circuits P.

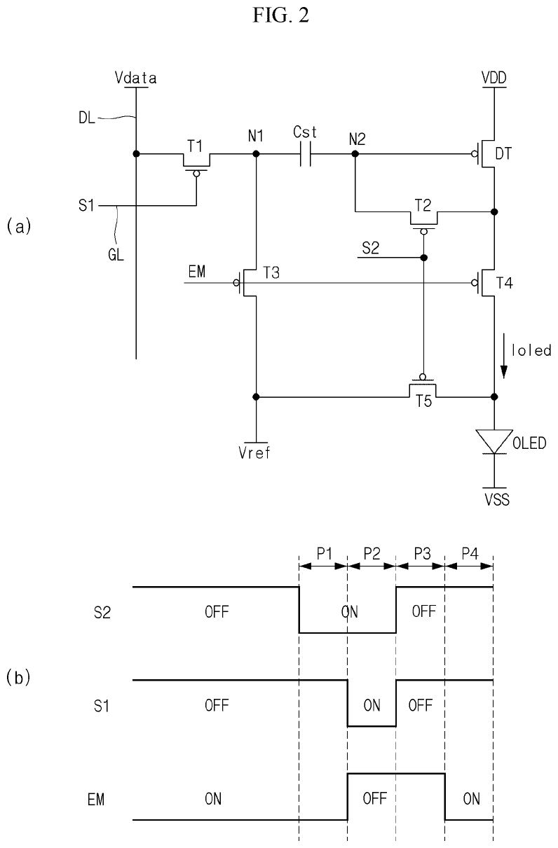

FIG. 2 illustrates an equivalent circuit and operation timing of each subpixel provided in the pixels illustrated in FIG. 1. The schematic diagram (a) in FIG. 2 is an example of a subpixel equivalent circuit, and the timing diagram (b) in FIG. 2 is an example of the operation timing of the equivalent circuit illustrated in the schematic diagram (a) in FIG. 2.

Although the schematic diagram (a) in FIG. 2 illustrates a case in which the subpixel equivalent circuit includes a PMOS transistor, the present disclosure is not limited thereto, and the subpixel equivalent circuit may be applied to cases in which the subpixel equivalent circuit includes an NMOS transistor or includes both a PMOS transistor and an NMOS transistor.

As illustrated in the schematic diagram (a) in FIG. 2, the subpixel equivalent circuit according to an example of the present disclosure may include transistors T1 to T5, a storage capacitor Cst, a driving transistor DT, and a light-emitting element OLED.

The transistor T1 may include a gate electrode that receives a first scan signal S1 through a gate line GL, a first electrode that receives a data voltage Vdata through a data line DL, and a second electrode connected to a first node N1. The transistor T1 may supply a data voltage Vdata to the first node N1 in response to the first scan signal S1 having a gate on voltage.

The storage capacitor Cst may be connected between the first node N1 and a second node N2 and may store a difference voltage between the voltage of the first node N1 and the voltage of the second node N2.

The driving transistor DT may include a gate electrode connected to the second node (N2), a first electrode to which a driving voltage VDD is applied, and a second electrode electrically connected to the light-emitting element OLED. The driving transistor DT can receive the driving voltage VDD and generate a driving current corresponding to the voltage of the second node N2. The magnitude of the driving current may depend on the voltage of the second node N2.

The transistor T2 may include a gate electrode that receives a second scan signal S2, a first electrode connected to the second electrode of the driving transistor DT, and a second electrode connected to the second node N2. The transistor T2 can electrically connect the second electrode of the driving transistor DT and the second node N2 in response to the second scan signal S2 having a gate on voltage. That is, while the transistor T2 is turned on, the transistor T2 can operate as a diode that connects the second electrode of the driving transistor DT to the second node N2.

The transistor T3 may include a gate electrode that receives an emission control signal EM, a first electrode that receives a reference voltage Vref, and a second electrode connected to the first node N1. The transistor T3 can initialize the first node N1 by supplying the reference voltage Vref to the first node N1 in response to the emission control signal EM having a gate on voltage.

The transistor T4 may include a gate electrode that receives the emission control signal EM, a first electrode connected to the driving transistor DT, and a second electrode connected to the light-emitting element OLED. The transistor T4 can supply the driving current generated in the driving transistor DT to the light-emitting element OLED in response to the emission control signal EM having the gate on voltage.

The transistor T5 may include a gate electrode that receives the emission control signal EM, a first electrode that receives the reference voltage Vref, and a second electrode connected to the anode of the light-emitting element OLED. The transistor T5 can supply the reference voltage Vref to the anode of the light-emitting element OLED in response to the second scan signal S2 having the gate on voltage, thereby initializing the anode of the light-emitting element OLED.

As shown in the timing diagram (b) in FIG. 2, the operation of the subpixel equivalent circuit may include an initialization period P1, a programming period P2, a holding period P3, and an emission period P4.

In the initialization period P1, the second scan signal S2 and the emission control signal EM have the gate on voltage, and thus the reference voltage Vref is supplied to the first node N1, the second node N2, and the anode of the light-emitting element OLED to initialize the first node N1, the second node N2, and the anode.

In the programming period P2, the threshold voltage Vth of the driving transistor DT may be sampled, and the data voltage Vdata may be programmed to the second node N2. Specifically, in the programming period P2, the first scan signal S1 and the second scan signal S2 have the gate on voltage, and thus the data voltage Vdata is supplied to the first node N1 and the sum of the driving voltage VDD and the threshold voltage Vth of the driving transistor DT is supplied to the second node N2 and stored in the storage capacitor Cst.

In the holding period P3, the first and second scan signals S1 and S2 and the emission control signal EM have the gate off voltage, and thus the first and second nodes N1 and N2 connected to the storage capacitor Cst can be floated.

In the emission period P4, the emission control signal EM has the gate on voltage, and thus the driving transistor DT can generate a driving voltage depending on the level of the voltage of the second node N2 connected to the storage capacitor Cst and supply the driving voltage to the light-emitting element OLED.

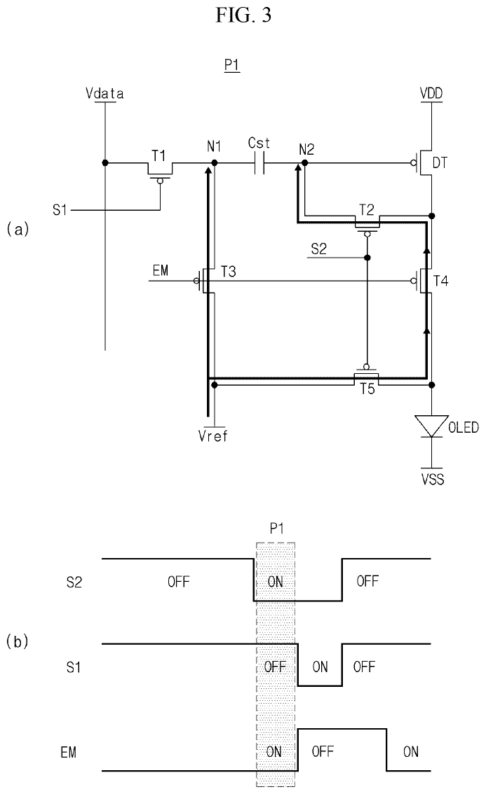

FIGS. 3 to 6 are diagrams for describing the specific operation of the subpixel equivalent circuit illustrated in FIG. 2.

As shown FIG. 3, in the initialization period P1, the second scan signal S2 and the emission control signal EM have the gate on voltage, and thus the transistors T2, T3, T4, and T5 can be turned on. Accordingly, the reference voltage Vref can be supplied to the first node N1 through the transistor T3, the reference voltage Vref can be supplied to the anode of the light-emitting element OLED through the transistor T5, and the reference voltage Vref can be supplied to the second node N2 through the transistors T5, T4, and T2.

Therefore, in the initialization period P1, the first and second nodes N1 and N2 and the anode of the light-emitting element OLED can be initialized to the reference voltage Vref.

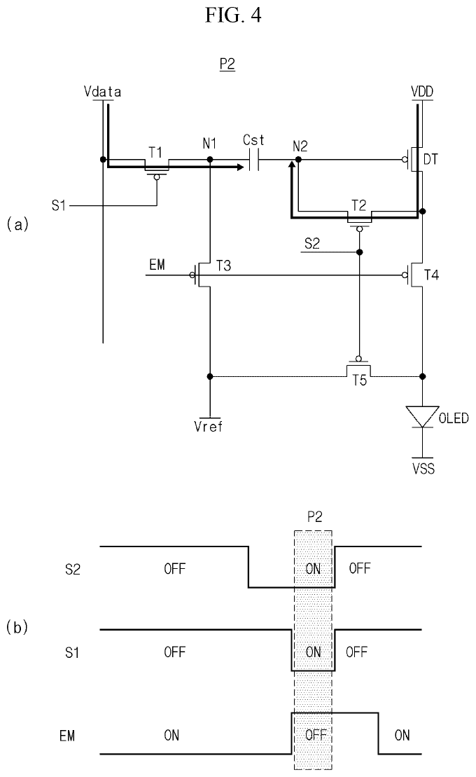

Thereafter, in the programming period P2, the first scan signal S1 and the second scan signal S2 have the gate on voltage, as shown in FIG. 4, and thus the transistors T1 and T3 and the driving transistor DT can be turned on.

Accordingly, the data voltage Vdata supplied to the data line DL can be supplied to the first node N1 through the transistor T1. In addition, as the driving voltage VDD is supplied to the second node N2 through the driving transistor DT and the transistor T2, a voltage VDD+Vth that is the sum of the driving voltage VDD and the threshold voltage Vth of the driving transistor DT can be supplied to the second node N2. At this time, the threshold voltage Vth of the driving transistor DT can be sampled.

Therefore, in the programming period P2, the difference between the voltage Vdata of the first node N1 and the voltage VDD+Vth of the second node N2 can be stored in the storage capacitor Cst.

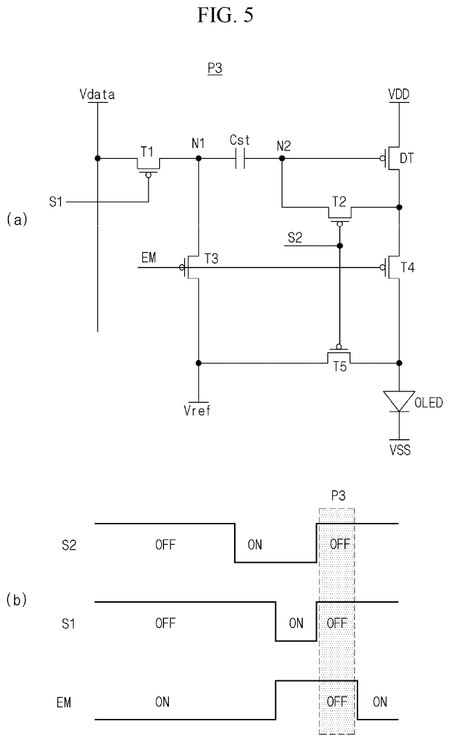

As shown in FIG. 5, in the holding period P3, the first and second scan signals S1 and S2 and the emission control signal EM have the gate off voltage, and thus the transistors T2, T3, and T5 can be turned on. Accordingly, the first and second nodes N1 and N2 to which the storage capacitor Cst is connected can be floated, the voltage of the first node N1 is maintained as Vdata, and the voltage of the second node N2 is maintained as VDD+Vth, and thus the voltage stored in the storage capacitor Cst in the programming period P2 can be remain unchanged in the holding period P3.

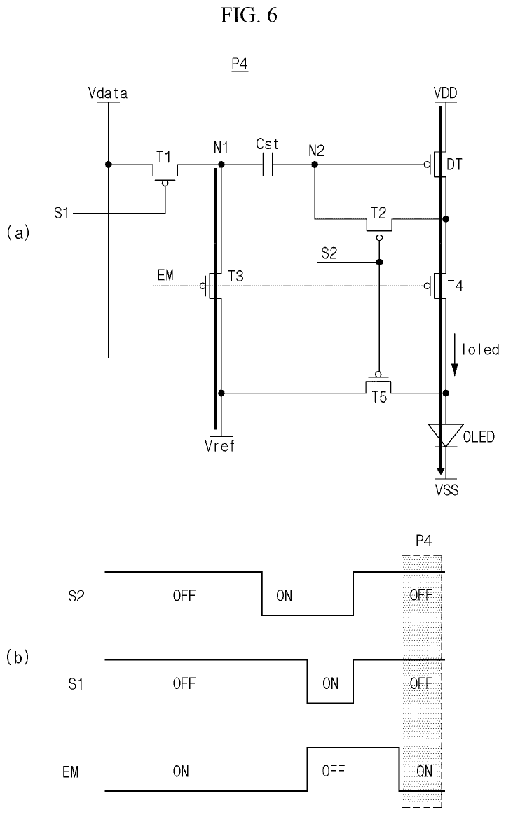

As shown in FIG. 6, in the emission period P4, the emission control signal EM has the gate on voltage, and thus the driving transistor DT and the transistors T3 and T4 can be turned on. Accordingly, the reference voltage Vref can be supplied to the first node N1 through the transistor T3, and the reference voltage Vref supplied to the first node N1 can be reflected by the storage capacitor Cst, and thus the voltage of the second node N2 becomes Vref−Vdata+VDD+Vth.

Accordingly, the driving transistor DT can generate a driving current according to the voltage (Vref−Vdata+VDD+Vth) of the second node N2, the generated driving current can be supplied to the light-emitting element OLED through the transistor T4, and the light-emitting element OLED can emit light having brightness according to the supplied driving current.

In the display device according to the present disclosure, the scan circuit GIA may be disposed in a distributed manner within the circuit area AS of the active area. Since the scan circuit GIA is positioned adjacent to the pixel circuit P as shown in FIG. 2, the data line DL connected to the pixel circuit P may be adjacent to a clock line of the scan circuit GIA.

In this case, since the data line DL is positioned adjacent to the clock line, mutual coupling may occur, and the data voltage Vdata applied through the data line DL may be distorted due to coupling. Accordingly, an image displayed on the display panel may be distorted.

In particular, such distortion of the data voltage Vdata may become more severe when the data voltage Vdata is time-divided through a MUX circuit and supplied to the plurality of data lines DL.

In order to reduce the number of source driver ICs in a high-resolution display panel, the data voltage Vdata may be time-divided and applied to a data line DL connected to one subpixel and a data line DL connected to another subpixel. In this case, a state in which the data line DL to which the data voltage Vdata is applied first by time division floats may occur. At this time, the data voltage Vdata applied to the floating data line DL may be distorted due to coupling with an adjacent clock line, and thus relatively severe image distortion may occur.

In order to minimize or at least reduce coupling between the clock line connected to the scan circuit GIA and the data line DL connected to the subpixel, the data line DL can be arranged far away from the clock line.

Hereinafter, the arrangement structure of the data lines DL of the subpixels within the pixel areas AP will be described.

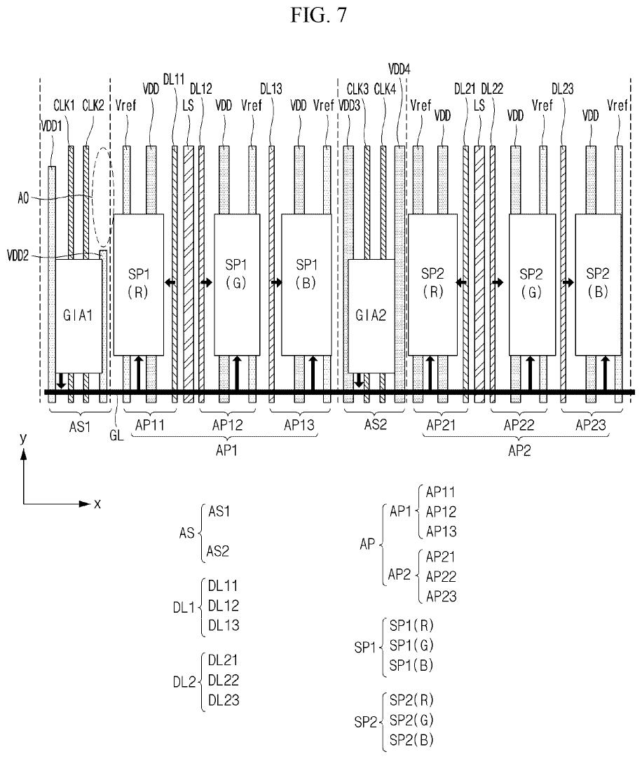

FIG. 7 is a diagram illustrating an arrangement structure of the data lines DL of the display panel according to a first embodiment of the present disclosure.

The plurality of circuit areas AS and the plurality of pixel areas AP illustrated in FIG. 7 correspond to a part of the display panel shown in FIG. 1, and the present disclosure is not necessarily limited to FIG. 7.

Hereinafter, for convenience of description, the left side of a component is described as one side, and the right side of the component is described as the other side.

As illustrated in FIG. 7, the display panel of the present disclosure may include a plurality of circuit areas AS and a plurality of pixel areas AP within the active area AA.

The plurality of circuit areas AS may include first and second circuit areas AS1 and AS2, and the plurality of pixel areas AP may include first and second pixel areas AP1 and AP2 that are alternately positioned with the first and second circuit areas AS1 and AS2. The first and second circuit areas AS1 and AS2 and the first and second pixel areas AP1 and AP2 illustrated in FIG. 7 may be repeated in the first direction x and the second direction y.

As illustrated in FIG. 7, a plurality of scan circuits GIA1 and GIA2 provided in the first and second circuit areas AS1 and AS2 and a plurality of subpixels SP1 and SP2 provided in the first and second pixel areas AP1 and AP2 may be electrically connected by a gate line GL extending in the first direction x.

The scan circuit GIA that generates a scan signal to be supplied to the gate line GL may be positioned in each of the first and second circuit areas AS1 and AS2. For example, a first scan circuit GIA1 may be located in the first circuit area AS1, and a second scan circuit GIA2 may be located in the second circuit area AS2. The first and second scan circuits GIA1 and GIA2 may each generate a scan signal and supply the scan signal (e.g., S1 in FIG. 2) to the gate line GL. Alternatively, the first and second scan circuits GIA1 and GIA2 may be electrically connected to each other to generate one scan signal, and the scan signal generated by the first and second scan circuits GIA1 and GIA2 may be supplied to the gate line GL.

In the first and second circuit areas AS1 and AS2, a plurality of clock lines CLK1 to CLK4 and a plurality of constant voltage lines VDD1 to VDD4 required for the first and second scan circuits GIA1 and GIA2 may extend in the second direction y and be connected to the first and second scan circuits GIA1 and GIA2.

A clock signal required for the operation of the first and second scan circuits GIA1 and GIA2 may be applied to each of the plurality of clock lines CLK1 to CLK4, and a high-level constant voltage or a low-level constant voltage required for the operation of the first and second scan circuits GIA1 and GIA2 may be applied to the plurality of constant voltage lines VDD1 to VDD4.

The plurality of constant voltage lines VDD1 to VDD4 may be disposed at both edges of the first and second circuit areas AS1 and AS2, and the plurality of clock lines CLK1 to CLK4 may be disposed between the constant voltage lines in the first and second circuit areas AS1 and AS2 (e.g., VDD1 and VDD2 in AS1, and VDD3 and VDD4 in AS2). Accordingly, the plurality of clock lines CLK1 to CLK4 can minimize or at least reduce coupling with data lines (e.g., DL11 and DL21) disposed in adjacent pixel areas AP1 and AP2.

The first and second pixel areas AP1 and AP2 may include first, second, and third subpixel areas that are sequentially arranged in a direction away from the first and second circuit areas AS1 and AS2.

For example, as illustrated in FIG. 7, the first pixel area AP1 located on the other side of the first circuit area AS1 may include first, second, and third subpixel areas AP11 to AP13 that are sequentially arranged in a direction away from the first circuit area AS1, and the second pixel area AP2 located on the other side of the second circuit area AS2 may include first, second, and third subpixel areas AP21 to AP23 that are sequentially arranged in a direction away from the second circuit area AS2.

In each of the first, second, and third subpixel areas AP11 to AP3 of the first and second pixel areas AP1 and AP2, first, second, and third subpixels SP1 and SP2 and first, second, and third data lines DL1 and DL2 that are connected to each of the first, second, and third subpixels may be disposed.

For example, as illustrated in FIG. 7, the first, second, and third subpixels SP1(R), SP1(G), and SP1(B) and the first, second, and third data lines DL11, DL12, and DL13 may be disposed in the first, second, and third subpixel areas AP11 to AP13 of the first pixel area AP1, respectively, and the first, second, and third subpixels SP2(R), SP2(G), and SP2(B) and the first, second, and third data lines DL21, DL22, and DL23 may be disposed in the first, second, and third subpixel areas AP21 to AP23 of the second pixel area AP2, respectively.

In the first and second pixel areas AP1 and AP2, the first, second and third data lines DL1 and DL2 may be connected to the first, second and third subpixels SP1 and SP2, respectively. The first, second and third subpixels SP1 and SP2 may each have the subpixel equivalent circuit illustrated in FIG. 2. The first, second and third subpixels SP1 and SP2 of the first and second pixel areas AP1 and AP2 may emit different colors.

For example, in the first and second pixel areas AP1 and AP2, the first subpixels SP1(R) and SP2(R) of the first subpixel area AP11 and AP21 may emit red (R), the second subpixels SP1(G) and SP2(G) of the second subpixel areas AP12 and AP22 may emit green (G), and the third subpixels SP1(B) and SP2(B) of the third subpixel areas AP13 and AP23 may emit blue (B).

In a case where the first and second circuit areas AS1 and AS2 and the first and second pixel areas AP1 and AP2 are alternately arranged, as shown in FIG. 7, in order to minimize or at least reduce coupling between the plurality of clock lines CLK1 to CLK4 disposed in the first and second circuit areas AS1 and AS2 and the plurality of data lines DL11, DL13, DL21, and DL23 disposed in the first and second pixel areas AP1 and AP2, the present disclosure may arrange the first and third data lines DL11, DL13, DL21, and DL23 disposed in the first and second pixel areas AP1 and AP2 to be spaced apart from the clock lines CLK1 to CLK4 disposed in the first and second circuit areas AS1 and AS2.

In each of the first, second, and third subpixel areas AP11 to AP23 of the first and second pixel areas AP1 and AP2, a reference voltage line Vref having a constant voltage and a driving voltage line VDD having a constant voltage may be disposed. The reference voltage line Vref and the driving voltage line VDD may be connected to each subpixel.

In the first and third subpixel areas AP11, AP13, AP21, and AP23 of the first and second pixel areas AP1 and AP2, the reference voltage line Vref and the driving voltage line VDD may be disposed between the first and second circuit areas AS1 and AS2 and the first and third data lines DL11, DL13, DL21, and DL23.

For example, the first data line DL11 disposed in the first subpixel area AP11 of the first pixel area AP1 may be positioned on a side of the first subpixel SP1(R) that is farther from the first circuit area AS1 than the other side, and the third data line DL13 disposed in the third subpixel area AP13 of the first pixel area AP1 may be positioned on a side of the third subpixel SP1(B) that is farther from the second circuit area AS2.

In addition, the first data line DL21 disposed in the first subpixel area AP21 of the second pixel area AP2 may be positioned on a side of the second subpixel SP2(R) that is farther from the second circuit area AS2, and the third data line DL23 disposed in the third subpixel area AP23 of the second pixel area AP2 may be positioned on a side of the third subpixel SP2(B) that is farther from the second circuit area AS1.

In this case, the second data lines DL12 and DL22 may be disposed adjacent to the first data lines DL11 and DL21 or the third data lines DL13 and DL23 in the first and second pixel areas AP1 and AP2. For example, in the case of FIG. 7, in order to minimize or at least reduce signal interference with the second data lines DL12 and DL22, a shield line LS may be disposed between the second data lines DL12 and DL22 and the data lines (e.g., DL11 and DL21) adjacent thereto in the present disclosure. Such a shield line LS is not connected to each subpixel, and a constant voltage is applied to the shield line LS.

In addition, in order to minimize or at least reduce coupling, the plurality of clock lines CLK1 to CLK4 may be disposed between the plurality of constant voltage lines VDD1 to VDD4 in the first and second circuit areas AS1 and AS2.

For example, the clock lines CLK1 and CLK2 may be disposed between the constant voltage lines VDD1 and VDD2 in the first circuit area AS1, and the clock lines CLK3 and CLK4 may be disposed between the constant voltage lines VDD3 and VDD4 in the second circuit area AS2.

Accordingly, interference caused by the clock lines in the first and second circuit areas AS1 and AS2 can be minimized or at least reduced using the constant voltage lines.

However, due to limitations in the area of the display panel caused by subpixels and scan circuits provided together in a small space, at least one of the first and second circuit areas AS1 and AS2 may have an open area AO in which the constant voltage line is not extended.

For example, as illustrated in FIG. 7, the second circuit area AS2 may not include the open area AO, but the first circuit area AS1 may include the open area AO in which the constant voltage line VDD2 is not extended.

Specifically, as illustrated in FIG. 7, in the second circuit area AS2, the constant voltage lines VDD3 and VDD4 may extend in the same manner as the clock lines CLK3 and CLK4, and thus the clock lines CLK3 and CLK4 may not directly face the third subpixel area AP13 of the adjacent first pixel area AP1 and the first subpixel area AP21 of the second pixel area AP2. Accordingly, signal interference due to the clock lines CLK3 and CLK4 can be minimized or at least reduced by being shielded by the constant voltage lines VDD3 and VDD4.

However, in the first circuit area AS1 in of FIG. 7, a certain constant voltage line (e.g., VDD2) may extend in in the second direction y, but may not extend into the open area AO. In such a case, the certain clock line (e.g., CLK2) may face the first subpixel area AP11 of the first pixel area AP1, and coupling may occur between the clock line (e.g., CLK2) and the first data line DL11 of the first pixel area AP1.

In order to minimize or at least reduce coupling, the present disclosure can dispose lines (e.g., Vref and VDD) having constant voltages between the first data line DL11 and the open area AO of the first circuit area AS1 and in the first subpixel area AP11. Here, the lines (e.g., Vref and VDD) having constant voltages may be electrically connected to the first subpixel SP1(R).

In this manner, the second and third data lines (e.g., DL12, DL13, DL22, and DL23) are positioned on one side of each subpixel in each of the first and second pixel areas AP1, AP2 in the present disclosure. However, in consideration of the first circuit area AS1 having the open area AO, the first data lines DL11 and DL21 may be positioned on the other sides of the first subpixels SP1(R) and SP2(R) opposite to the second and third data lines in the first and second pixel areas AP1 and AP2. Accordingly, the present disclosure can reduce coupling due to the clock lines of the first circuit area AS1.

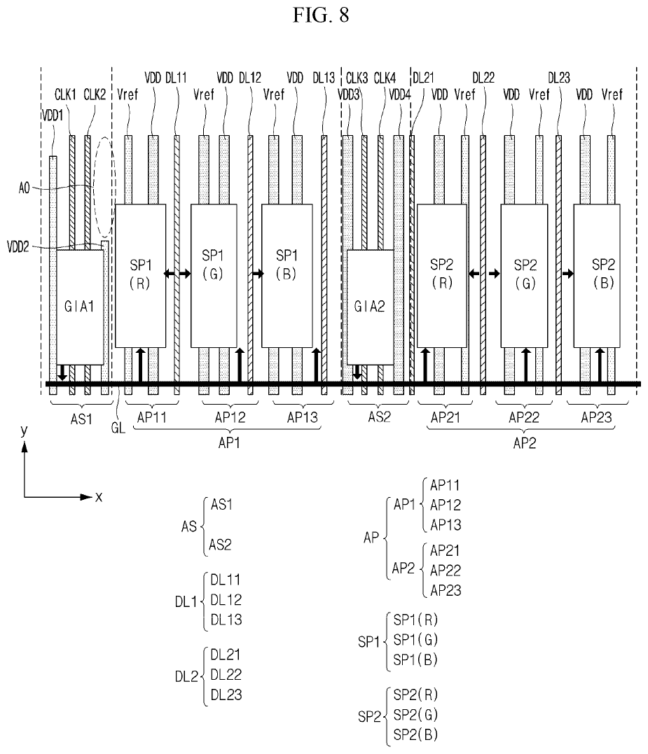

However, the present disclosure is not necessarily limited to the structure of FIG. 7. For example, the present disclosure may arrange the first, second, and third data lines in the first and second pixel areas AP1 and AP2 such that the first, second, and third data lines are relatively far away from the first circuit area AS1 having the open area AO and are adjacent to the second circuit area AS2 without the open area AO. This will be described with reference to FIG. 8 as follows.

FIG. 8 is a diagram illustrating an arrangement structure of data lines DL of the display panel according to a modification example of the first embodiment of the present disclosure.

Redundant description in FIG. 7 and FIG. 8 is omitted and differences from FIG. 7 will be mainly described in FIG. 8.

As illustrated in FIG. 8, the first, second, and third data lines DL1 and DL2 of the first and second pixel areas AP1 and AP2 may be designed to be symmetrical with respect to the second circuit area AS2 without the open area AO. In FIG. 8, the first circuit area AS1 may have the open area AO as described above in FIG. 7, and the second circuit area AS2 may not have the open area AO.

The first, second, and third data lines DL11, DL12, and DL13 of the first pixel area AP1 may be disposed on sides of the first, second, and third subpixels SP1, which are adjacent to the second circuit area AS2. That is, the first, second, and third data lines DL11, DL12, and DL13 of the first pixel area AP1 may be disposed on the other sides of the first, second, and third subpixels SP1 that are spaced away from the first circuit area AS1 having the open area AO.

In addition, the first, second, and third data lines DL21, DL22, and DL23 of the second pixel area AP2 may be disposed on sides of the first, second, and third subpixels SP2 of the second pixel area AP2, which are adjacent to the second circuit area AS2.

In this manner, in the present disclosure, the first, second, and third data lines DL1 of the first pixel area AP1 and the first, second, and third data lines DL2 of the second pixel area AP2 may be disposed to be symmetrical with respect to the second circuit area AS2. Accordingly, the first and second pixel areas AP1 and AP2 may be examined as one set area during product inspection of the display panel, thereby further improving the efficiency of the inspection.

In the case of FIG. 8, the reference voltage line Vref and the driving voltage line VDD may be disposed between the second data line DL and the first and third data lines DL in each of the first and second pixel areas AP1 and AP2, and thus the shield line LS described in FIG. 7 can be omitted.

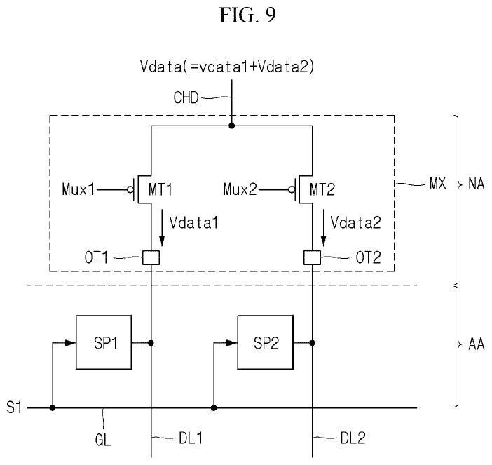

The arrangement structure of the data lines DL described in FIGS. 7 and 8 can more effectively prevent distortion of the data voltage Vdata by minimizing or at least reducing coupling for floating data lines DL when the high-resolution display panel is operated by multiplexing the plurality of data lines DL. This will be described with reference to FIGS. 9 to 11.

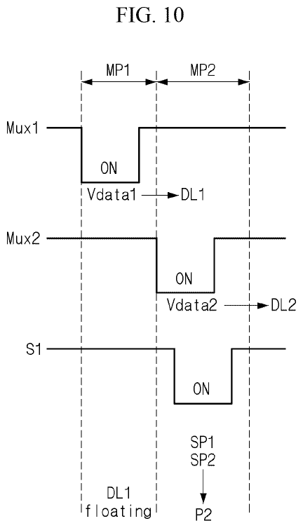

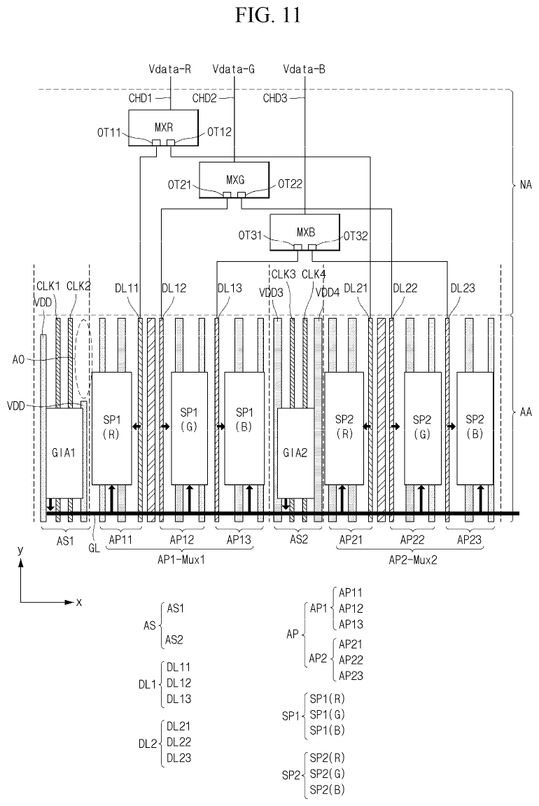

FIG. 9 is a diagram illustrating a multiplexer circuit MX according to one or more embodiments of the present disclosure, FIG. 10 is a timing diagram for describing an operation method of the multiplexer circuit MX shown in FIG. 9, and FIG. 11 is a diagram illustrating an example in which the multiplexer circuit MX of FIG. 9 is applied to a display panel.

FIG. 11 illustrates an example in which a multiplexer circuit MX of the present disclosure is applied to a display panel having an arrangement structure of data lines DL according to the first embodiment illustrated in FIG. 7, but the present disclosure is not limited thereto. For example, the multiplexer circuit MX of the present disclosure may be applied to a display panel having an arrangement structure of data lines DL according to a second embodiment illustrated in FIG. 8, and may also be applied to display panels having other arrangement structures of data lines DL.

Hereinafter, for convenience of explanation, an example of a case in which the multiplexer circuit MX of the present disclosure has the arrangement structure of data lines DL according to the first embodiment illustrated in FIG. 7 will be described, as illustrated in FIG. 11.

In the case of high-resolution display panels, the number of data lines DL increases significantly, and as the number of data lines DL increases, the number of source driver ICs that apply a data voltage Vdata may also increase.

In the case of a high-resolution display panel, the present disclosure may dispose a multiplexer circuit MX in a non-active area AA as illustrated in FIG. 9 in order to reduce the number of source driver ICs.

The multiplexer circuit MX may be disposed in the non-active area AA, and may be positioned in a region adjacent to the first and second pixel areas AP1 and AP2.

The multiplexer circuit MX may receive a data signal from a source driver IC included in the data driver 13 and sequentially output a data voltage Vdata to the first data line DL1 of the first pixel area AP1 and the first data line DL2 of the second pixel area AP2.

The first and second pixel areas AP1 and AP2 may be, for example, pixel areas described in FIG. 7 or FIG. 8, the first data line DL1 may be a data line disposed in a subpixel area of the first pixel area AP1, and the second data line DL2 may be a data line disposed in a subpixel area of the second pixel area AP2.

For example, subpixels emitting the same color may be disposed in the first and second subpixel areas AP1 and AP2, and the first and second data lines DL1 and DL2 may be included in different unit pixels and connected to subpixels emitting the same color.

As illustrated in FIG. 9, the multiplexer circuit MX may include a first MUX transistor MT1 and a second MUX transistor MT2 which have input terminals commonly connected to a data channel CHD of a source driver IC included in the data driver 13 and output terminals connected to data lines of different pixel areas.

The first MUX transistor MT1 may include a gate electrode that receives a first MUX signal Mux1, a first electrode connected to the data channel CHD of the data driver 13, and a second electrode connected to the first subpixel located in the first pixel area AP1 via the first data line DL1. The second electrode of the first MUX transistor may be a first output terminal OT1 of the multiplexer circuit.

The second MUX transistor MT2 may include a gate electrode that receives a second MUX signal Mux2, a first electrode connected to the data channel CHD, and a second electrode connected to the second subpixel located in the second pixel area AP2 via the second data line DL2. The second electrode of the second MUX transistor may be a second output terminal OT2 of the multiplexer circuit.

The first electrodes of the first and second MUX transistors MT1 and MT2 may be input terminals of the multiplexer circuit MX and may be commonly connected to one channel CHD provided in the source driver IC. The first output terminal OT1 of the multiplexer circuit MX may be connected to the first data line DL1 of the first subpixel SP1, and the second output terminal OT2 of the multiplexer circuit MX may be connected to the second data line DL2 of the second subpixel SP2.

Here, the first subpixel SP1 may be a subpixel located in one of the plurality of subpixel areas AP11 to AP13 provided in the first pixel area AP1, and the second subpixel SP2 may be a subpixel located in one of the plurality of subpixel areas AP21 to AP23 provided in the second subpixel area AP2. Here, the first and second subpixels may emit the same color and may be connected to the same gate line GL to receive the same first scan signal S1.

Data signals input to the data channel CHD may include a first data signal Vdata1 and a second data signal Vdata2. The first data signal Vdata1 may be applied to the first subpixel through the first data line DL1 of the first pixel area AP1, and the second data signal Vdata2 may be applied to the subpixel through the second data line DL2 of the second pixel area AP2.

As illustrated in FIGS. 9 and 10, the first data signal Vdata1 may be output to the first data line DL1 of the first pixel area AP1 through the first MUX transistor MT1 when the first MUX signal Mux1 has a turn-on voltage in a first MUX period MP1, and the second data signal Vdata2 may be output to the second data line DL2 of the second pixel area AP2 through the second MUX transistor MT2 when the second MUX signal Mux2 has a turn-on voltage in a second MUX period MP2.

In the first MUX period MP1, the first data line DL1 to which the first data signal Vdata1 has been applied may float until the first scan signal S1 having the turn-on voltage is applied to the gate line GL.

Thereafter, when the second data signal Vdata2 is applied to the second data line DL2 in the second MUX period MP2, and the first scan signal S1 having the turn-on voltage is applied to the gate line GL in the programming period P2 described in FIGS. 2 to 6, the first data voltage Vdata of the first data line DL1 may be input to the first subpixel, and the second data voltage Vdata of the second data line DL2 may be input to the second subpixel in response to the first scan signal S1.

The multiplexer circuit MX described above may be connected to the first, second, and third subpixel areas AP11 to AP23 included in the first and second pixel areas AP1 and AP2, as illustrated in FIG. 11.

For example, an input terminal of a first multiplexer circuit MX1 may be connected to a first data channel CHD-R of the source driver IC, a first output terminal OT11 of the first multiplexer circuit MX1 may be connected to the first data line DL11 connected to the first subpixel SP1-(R) of the first pixel area AP1, and a second output terminal OT12 of the first multiplexer circuit MX1 may be connected to the first data line DL21 connected to the first subpixel SP2-(R) of the second pixel area AP2.

An input terminal of a second multiplexer circuit MX2 may be connected to a second data channel CHD-G of the source driver IC, a first output terminal OT21 of the second multiplexer circuit MX2 may be connected to the second data line DL12 connected to the second subpixel SP1-(G) of the first pixel area AP1, and a second output terminal OT22 of the second multiplexer circuit MX2 may be connected to the second data line DL22 connected to the second subpixel SP2-(G) of the second pixel area AP2.

An input terminal of a third multiplexer circuit MX3 may be connected to a third data channel CHD-B of the source driver IC, a first output terminal OT31 of the third multiplexer circuit MX3 may be connected to the third data line DL13 connected to the third subpixel SP1-(B) of the first pixel area AP1, and a second output terminal OT32 of the third multiplexer circuit MX3 may be connected to the third data line DL23 connected to the third subpixel SP2-(B) of the second pixel area AP2.

When the first, second, and third multiplexer circuits MX1 to MX3 are applied to the non-active area NA of the display panel, as illustrated in FIG. 11, after each of the first, second, and third multiplexer circuits MX1 to MX3 outputs a first data voltage Vdata to each of the first, second, and third data lines DL1 located in the first pixel area AP1, the first, second, and third data lines DL1 can float until the first scan signal S1 is applied to the gate line GL.

Each of the first, second, and third multiplexer circuits MX1 to MX3 outputs a second data voltage Vdata to each of the first, second, and third data lines DL2 located in the second pixel area AP2, and when the turn-on voltage of the first scan signal S1 is applied to the gate line GL, the first data voltage Vdata1 of each of the first, second, and third data lines DL1 located in the first pixel area AP1 and the second data voltage Vdata2 of each of the first, second, and third data lines DL2 located in the second pixel area AP2 can be input to each of the subpixels SP1 and SP2.

In this case, the first data voltage Vdata1 of each of the first, second, and third data lines DL1 located in the first pixel area AP1 may become unstable due to floating until the first scan signal S1 is applied.

In particular, since the first subpixel area AP11 is directly adjacent to the open area AO of the first circuit area AS1, the first data line DL11 of the first subpixel area AP11 may be relatively greatly affected by coupling due to a clock line (e.g., CLK2) of the first circuit area AS1.

However, the present disclosure takes this into consideration and can minimize or at least reduce the coupling effect due to a clock line (e.g., CLK2) of the first circuit area AS1 by disposing the first data line DL11 located in the first subpixel area AP11 on the other side of the first subpixel SP1(R) which is relatively far from the first circuit area AS1, and disposing the reference voltage line Vref and the driving voltage line VDD between the first data line DL11 and the open area AO of the first circuit area AS1.

A configuration in which the arrangement structure of the data lines DL disposed in the pixel area AP is improved in order to reduce signal interference such as coupling due to a clock line located in the circuit area AS has been described. However, the present disclosure is not necessarily limited thereto.

Hereinafter, another example of a structure for reducing signal interference such as coupling due to a clock line disposed in a circuit area AS according to the present disclosure will be described.

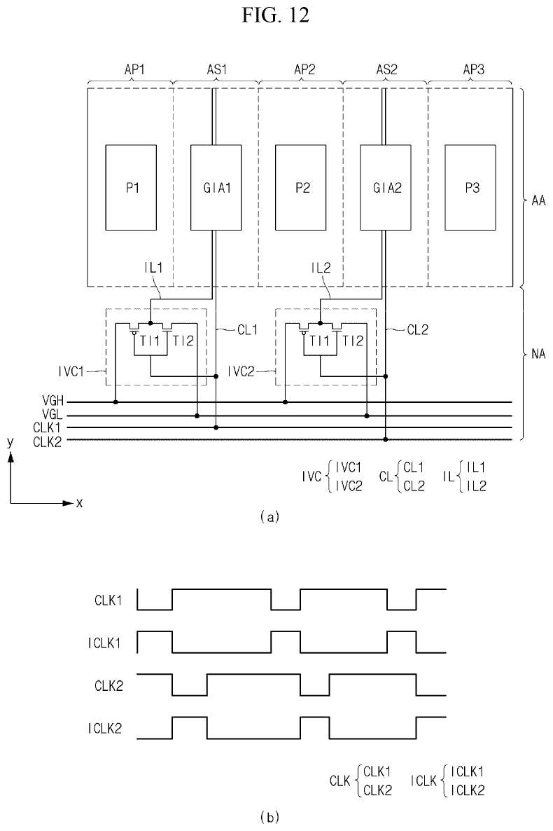

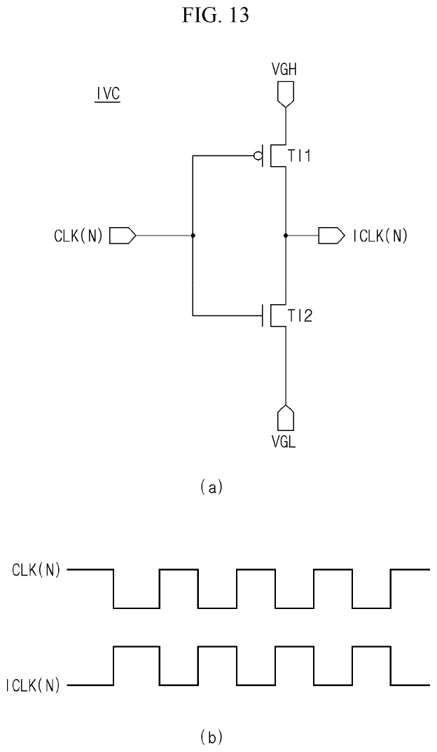

FIG. 12 illustrates a first example of a structure in which a display panel includes an inverter circuit IVC according to a second embodiment of the present disclosure, and FIG. 13 is a diagram illustrating the inverter circuit IVC illustrated in FIG. 12 in detail.

The schematic diagram (a) in FIG. 12 is a schematic diagram showing a structure in which the inverter circuit IVC is provided on the display panel 10, and the timing diagram (b) in FIG. 12 is an example for describing a clock signal CLK applied to a clock line CL and an inverted clock signal ICLK applied to an inverted clock line IL.

In the first example of the structure in which the display panel 10 includes the inverter circuit IVC according to the second embodiment of the present disclosure, as illustrated in the schematic diagram(a) in FIG. 12, a plurality of pixel areas and a plurality of circuit areas AS1 and AS2 are alternately arranged in the active area AA, while at least one inverter circuit IVC may be provided in the non-active area NA. The schematic diagram (a) in FIG. 12 illustrates an example in which the inverter circuit IVC includes first and second inverter circuits IVC1 and IVC2 and is provided on the display panel 10.

In the circuit areas AS1 and AS2, a clock line CL and an inverted clock line IL are disposed adjacent to each other and may extend in the second direction y. That is, the inverted clock line IL may be disposed adjacent to the clock line CL within the same circuit areas AS1 and AS2 and extend in the second direction y parallel to the clock line CL.

The inverted clock line IL may extend along the clock line CL within the circuit areas AS1 and AS2. That is, the inverted clock line IL may extend parallel to the clock line CL while maintaining a predetermined distance. For example, when the clock line CL is bent within the circuit areas AS1 and AS2, the inverted clock line IL can also be bent at the point where the clock line CL is bent.

The clock line CL and the inverted clock line IL may extend in parallel in the second direction y in the circuit areas AS1 and AS2, and the inverted clock line IL may extend apart from the clock line CL in the first direction x (i.e., horizontal direction) or in a thickness direction z.

The clock line CL to which a clock signal CLK is applied may extend along the circuit areas AS1 and AS2 and be connected to scan circuits GIA1 and GIA2, and the inverted clock line IL to which an inverted clock signal ICLK is applied may extend along the circuit areas AS1 and AS2 from the first and second inverter circuits IVC1 and IVC2. The inverted clock line IL may not be connected to the scan circuits GIA1 and GIA2, and the end of the inverted clock line IL in the circuit areas AS1 and AS2 may be open without being connected to any circuit.

As illustrated in the timing diagram (b) in FIG. 12, the clock signal CLK may be applied to the clock line CL, and an inverted clock signal ICLK may be applied to the inverted clock line IL. That is, when the clock signal CLK has a gate high voltage, the inverted clock signal ICLK has a gate low voltage, and when the clock signal CLK has the gate low voltage, the inverted clock signal ICLK has the gate high voltage.

The inverter circuit IVC is positioned adjacent to an area where the clock line CL and the inverted clock line IL are disposed in the non-active area NA, and may receive the clock signal CLK supplied to the scan circuits GIA1 and GIA2, invert the clock signal CLK, and output the inverted clock signal ICLK.

Although the schematic diagram (a) in FIG. 12 illustrates an example in which the inverter circuit IVC is positioned adjacent to each of the circuit areas AS1 and AS2 in the non-active area NA, the present disclosure is not necessarily limited to FIG. 12(a). For example, the inverter circuit IVC may be selectively disposed adjacent to a circuit area having the open area AO among the plurality of circuit areas AS1 and AS2.

For example, in a case where the first circuit area AS1 has the open area AO and the second circuit area AS2 does not have the open area AO in FIG. 12(a), the second inverter circuit IVC2 of the first and second inverter circuits IVC1 and IVC2 may be omitted.

For example, when the first and second inverter circuits IVC1 and IVC2 illustrated in the schematic diagram (a) in FIG. 12 are applied to the display panel 10 shown in FIG. 7, the first inverter circuit IVC1 may be disposed adjacent to the first circuit area AS1 having the open area AO, and the second inverter circuit IVC2 may be disposed adjacent to another circuit area having the open area AO. In this case, the clock line CL1 connected to the output terminal of the first inverter circuit IVC1 may be the second clock line CLK2 illustrated in FIG. 7.

In addition, in a case where each of the plurality of circuit areas AS1 and AS2 includes the open area AO, the first and second inverter circuits IVC1 and IVC2 may be positioned adjacent to the circuit areas AS1 and AS2 in the non-active area NA, as illustrated in the schematic diagram (a) in FIG. 12, but the present disclosure is not necessarily limited to the schematic diagram (a) in FIG. 12. Unlike the timing diagram (b) in FIG. 12, in a case where first and second clock signals CLK1 and CLK2 are synchronized with each other, one of the first and second inverter circuits IVC1 and IVC2 in the schematic diagram (a) in FIG. 12 may be omitted.

More specifically, unlike the timing diagram (b) in FIG. 12, in a case where the second clock signal CLK2 has the gate high voltage when the first clock signal CLK1 has the gate high voltage, and the second clock signal CLK2 has the gate low voltage when the first clock signal CLK1 has the gate low voltage, for example, the second inverter circuit IVC2 of the first and second inverter circuits IVC1 and IVC2 may be omitted, and the output terminal of the first inverter circuit IVC1 may be commonly connected to a first inverted clock line IL1 extending to the first circuit area AS1 and a second inverted clock line IL2 extending to the second circuit area AS2 such that the first inverted clock signal ICLK1 of the first inverter circuit IVC1 is applied to both the first inverted clock line IL1 and the second inverted clock line IL2 in the schematic diagram (a) in FIG. 12 in the present disclosure.

As shown in the schematic (a) in FIG. 12, when the inverter circuit IVC and the inverted clock line IL are provided, if the open area AO is present in the circuit areas AS1 and AS2 where the clock line CL is disposed, signal interference caused by the clock line CL, which is applied to adjacent pixel areas, can be reduced.

For example, in the present disclosure, if the open area AO is present in the first and second circuit areas AS1 and AS2 due to limitation in the area, the waveform of the clock signal CLK is offset by the waveform of the inverted clock signal ICLK through the inverted clock line IL that extends parallel to and adjacent to the clock line CL, thereby minimizing or at least reducing signal interference caused by coupling that may be applied by the clock signal CLK of the clock line CL to the pixels of the pixel areas AP1 to AP3 adjacent to the first and second circuit areas AS1 and AS2.

As illustrated in the schematic diagram (a) in FIG. 13, the inverter circuit IVC may include a first inverter transistor TI1 and a second inverter transistor TI2 which have input terminals commonly connected to the clock line CL and output terminals commonly connected to the inverted clock line IL.

The first inverter transistor TI1 may have a gate electrode connected to the clock line CL, a first electrode to which the gate high voltage VGH is applied, and a second electrode connected to the inverted clock line IL. The second inverter transistor TI2 may have a gate electrode connected to the clock line CL, a first electrode to which the gate low voltage VGL is applied, and a second electrode connected to the inverted clock line IL. Here, the first inverter transistor TI1 may be a PMOS transistor, and the second inverter transistor TI2 may be an NMOS transistor.

As shown in the timing diagram (b) in FIG. 13, when the clock signal CLK having the gate low voltage VGL is applied to the clock line CL connected to the input terminal of the inverter circuit IVC, the first inverter transistor TI1 is turned on, and thus the inverted clock signal ICLK having the gate high voltage VGH can be output to the inverted clock line IL.

In addition, when the clock signal CLK having the gate high voltage VGH is applied to the clock line CL, the second inverter transistor TI2 is turned on, and thus the inverted clock signal ICLK having the gate low voltage VGL can be output to the inverted clock line IL.

Accordingly, the inverted clock signal ICLK having a voltage opposite to that of the clock signal CLK can be output to the inverted clock line IL connected to the output terminal of the inverter circuit IVC.

The present disclosure can dispose the inverted clock line IL adjacent to the clock line CL to cancel a noise signal caused by the clock signal CLK. In this case, as described above with reference to FIG. 7, when the open area AO is present in the circuit area AS1, the noise signal caused by the clock signal CLK can be canceled to prevent the data voltage supplied to subpixels adjacent to the open area AO from being unstable due to the clock signal CLK.

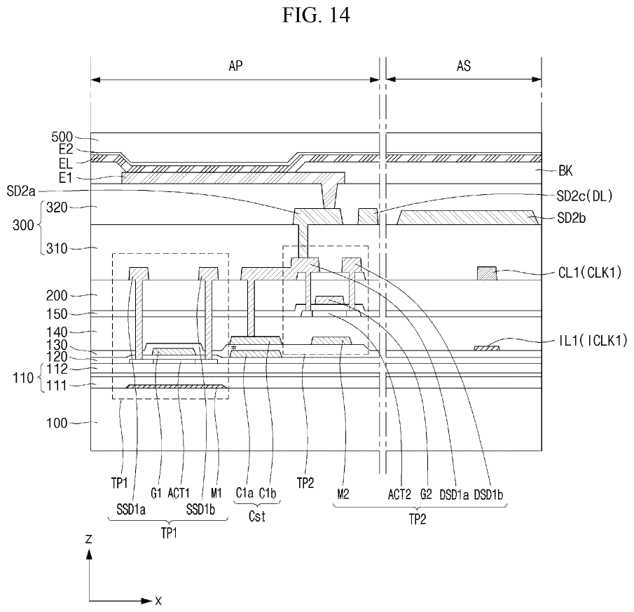

Hereinafter, a cross-sectional structure of the display panel 10 including the clock line CL and the inverted clock line IL of the present disclosure will be described with reference to FIG. 14.

The clock line CL and the inverted clock line IL of the present disclosure may extend and be spaced apart in the horizontal direction or in the thickness direction z of the display panel 10 as described above. In FIG. 14, a structure in which the clock line CL and the inverted clock line IL are spaced apart in the thickness direction z in the circuit areas AS1 and AS2 is described.

FIG. 14 is a diagram showing an example illustrating a cross section of the display panel according to the first example of the second embodiment of the present disclosure illustrated in FIG. 12.

Hereinafter, for convenience of description, a pixel area AP of the display panel 10 will be described first, and then a circuit area AS of the display panel 10 will be described. Although transistor elements are not illustrated in the circuit area AS in FIG. 14, the circuit area AS may also include transistors that constitute a scan circuit GIA. However, in FIG. 14, the transistors are omitted and the clock line CL and the inverted clock line IL are mainly illustrated for convenience of understanding.

A substrate 100, a substrate buffer layer 110, a first gate insulating film 120, a lower interlayer insulating film 130, an element buffer layer 140, a second gate insulating film 150, an upper interlayer insulating film 200, a planarization film 300, intermediate electrodes SD2a and SD2b, a bank BK, a light-emitting element OLED, and an encapsulation layer 500 may be disposed in the pixel area AP and the circuit area AS of the display panel 10 according to an embodiment of the present disclosure illustrated in FIG. 14.

In addition, a switching transistor ST, a storage capacitor Cst, and a driving transistor DT may be disposed in the pixel area AP, and the clock line CL and the inverted clock line IL extending in the second direction y may be disposed in the circuit area AS. The switching transistor ST of the pixel area AP may be any one of the transistors T1 to T5 described above with reference to FIGS. 2 to 6.

The substrate 100 may be formed of a flexible plastic material and may have flexibility. The substrate 100 may also include thin glass having flexibility. The substrate 100 may be placed in the active area AA and the non-active area NA of the display panel 10.

The substrate 100 may have a multilayer structure including an insulating material. For example, the substrate 100 may include a polymer material such as polyimide (PI) and an insulating material.

The substrate buffer layer 110 may be disposed on the substrate 100 in the active area AA and the non-active area NA. The substrate buffer layer 110 may be disposed on the substrate 100 to protect structures on the substrate 100 that are vulnerable to moisture penetration from the outside and to flatten the surface of the substrate 100.

The substrate buffer layer 110 may include an insulating material, may include an inorganic insulating material such as silicon oxide (SiOx) and silicon nitride (SiNx), and may include a multilayer structure containing the same material or different materials.

For example, the substrate buffer layer 110 may include a multi-buffer layer 111 containing different insulating materials and an active buffer layer 112, which are laminated.

The first gate insulating film 120 may be disposed on the active buffer layer 112 of the substrate buffer layer 110. The first gate insulating film 120 may include at least one inorganic insulating material among silicon oxide (SiOx), silicon nitride (SiNx), and silicon oxynitride (SiOxNy).

The lower interlayer insulating film 130 may be disposed on the first gate insulating film 120. The lower interlayer insulating film 130 may contain an inorganic insulating material, and may include one or more inorganic films of a silicon oxide film (SiOx), a silicon nitride film (SiNx), and a silicon oxynitride film (SiOxNy).

The element buffer layer 140 may be disposed on the lower interlayer insulating film 130. The element buffer layer 140 may include an inorganic insulating material. For example, the element buffer layer 140 may include an inorganic insulating material such as silicon oxide (SiOx) and silicon nitride (SiNx).

The second gate insulating film 150 may be disposed on the first element buffer layer 140 (141), and the second gate insulating film 150 may include at least one inorganic insulating material among silicon oxide (SiOx), silicon nitride (SiNx), and silicon oxynitride (SiOxNy).

The upper interlayer insulating film 200 may be disposed on the second gate insulating film 150, and may be formed as a multilayer structure including an insulating material such as silicon oxide (SiOx), silicon nitride (SiNx), or silicon oxynitride (SiOxNy).

The planarization film 300 may be disposed on the upper interlayer insulating film 200 and may include an insulating material. The planarization film 300 may remove stepped portions caused by a plurality of transistors disposed in each subpixel SP. The upper surface of the planarization film 300 may be flat and may include a material having high fluidity. For example, the planarization film 300 may include an organic insulating material.

The planarization film 300 may have a multilayer structure in which a plurality of layers is laminated, and for example, the planarization film 300 may include a first planarization film 310 and a second planarization film 320 that are sequentially laminated.

The first planarization film 310 may remove stepped portions caused by driving circuits such as the switching transistor ST and the driving transistor DT. The first planarization film 310 and the second planarization film 320 may have flat surfaces. To this end, the first and second planarization films 310 and 320 may include the same or different fluidic organic insulating materials.

First and second intermediate electrodes SD2a and SD2b may be disposed between the first planarization film 310 and the second planarization film 320. The first and second intermediate electrodes SD2a and SD2b may include a conductive material, and may include, for example, a metal such as aluminum (Al), chromium (Cr), copper (Cu), titanium (Ti), molybdenum (Mo), and tungsten (W). The first intermediate electrode SD2a may be positioned in the pixel area AP, and the second intermediate electrode SD2b may be positioned in the circuit area AS.

The first intermediate electrode SD2a may electrically connect the light-emitting element OLED and the driving transistor DT in each subpixel SP. For example, the first intermediate electrode SD2a may electrically connect the driving transistor DT and a first electrode E1 (anode) of the light-emitting element OLED by penetrating the first and second planarization films 310 and 320.

The bank BK may be located on the planarization film 300. The bank BK may define an emission area of each subpixel, and the area of each subpixel may be defined by the bank BK. The light-emitting element OLED may be located in the emission area.

The bank BK may include an organic insulating material. The bank BK may cover an edge of the first electrode 610 (e.g., anode). An emission layer EL and a second electrode E2 (e.g., cathode) may be laminated on a portion of the first electrode E1 exposed by the bank BK.

The light-emitting element OLED is positioned on the planarization film 300 and may include the first electrode E1, the emitting layer EL, and the second electrode E2. The light-emitting element OLED may emit any one color of red (R), green (G), and blue (B).

The first electrode E1 serving as the anode may include a conductive material, for example. The first electrode E1 may have high reflectivity. For example, the first electrode E1 may include a metal such as aluminum (Al) and silver (Ag). The first electrode E1 may have a multilayer structure. For example, the first electrode E1 may have a structure in which a reflective electrode made of a metal is positioned between transparent electrodes made of transparent conductive materials such as ITO and IZO.

The emission layer EL may generate light having brightness corresponding to a voltage difference between the first electrode E1 and the second electrode E2. For example, the emission layer EL may include an emission material layer (EML) containing an emission material. The emission material may include an organic material, an inorganic material, or a hybrid material. For example, the emission layer EL may include an emission material layer made of an organic material.

The emission layer EL may include at least one of a first emission common layer (not shown) positioned between the emission layer EL and the first electrode E1 and a second emission common layer (not shown) positioned between the emission layer EL and the second electrode E2. The first emission common layer (not shown) and the second emission common layer (not shown) may each include at least one of a hole injection layer (HIL), a hole transport layer (HTL), an electron transport layer (ETL), and an electron injection layer (EIL).

The second electrode E2 serving as the cathode may include a conductive material, for example. The second electrode E2 may include a different material from the first electrode E1. For example, the second electrode E2 may be a transparent electrode made of a transparent conductive material such as ITO or IZO. The second electrode E2 may have a higher transmittance than the first electrode E1. Accordingly, in the display panel 10 according to the embodiment of the present disclosure, light generated by the emission layer EL can be emitted through the second electrode E2.

The encapsulation layer 500 may be positioned on the light-emitting element OLED. The encapsulation layer 500 may prevent damage to the light-emitting elements OLED due to external impact and moisture. The encapsulation layer 500 may have a multilayer structure. For example, the encapsulation layer 500 may be formed by alternately laminating an encapsulation layer 500 made of an inorganic insulating material and an encapsulation layer 500 made of an organic insulating material. Accordingly, in the display panel 10 according to the embodiment of the present disclosure, damage to the light-emitting element OLED due to external impact and moisture can be effectively prevented.

The storage capacitor Cst may be positioned on the first gate insulating film 120 of the pixel area AP. For example, the storage capacitor Cst may have a first electrode plate C1a and a second electrode plate C1b, the first electrode plate C1a may be disposed between the first gate insulating film 120 and the lower interlayer insulating film 130, the second electrode plate C1b may be disposed between the lower interlayer insulating film 130 and the element buffer layer 140, and the first and second electrode plates C1a and C1b may be insulated from each other by the lower interlayer insulating film 130.

In the storage capacitor Cst, the first electrode plate C1a may be connected to an electrode of another switching element (not shown), and the second electrode plate C1b may be electrically connected to one of the source and drain electrodes DSD1a of the driving transistor DT, as shown in FIG. 14.

The switching transistor ST may be electrically connected to the driving transistor DT and may constitute one of the transistors in the pixel equivalent circuit illustrated in the schematic (a) in FIG. 2.

The switching transistor ST may include a first gate electrode G1, a first semiconductor layer ACT1, a first source electrode SSD1a, a first drain electrode SSD1b, and a first metal layer M1.

The first gate electrode G1 may be disposed between the first gate insulating film 120 and the lower interlayer insulating film 130. The first gate electrode G1 may be located in the same layer as the first electrode plate C1a of the storage capacitor Cst and may include the same conductive material, for example, a metal such as aluminum (Al), chromium (Cr), copper (Cu), titanium (Ti), molybdenum (Mo), or tungsten (W).

The first semiconductor layer ACT1 overlaps the first gate electrode G1, may be disposed between the substrate buffer layer 110 and the first gate insulating film 120, and may include a low-temperature polycrystalline silicon (LTPS) semiconductor material. The first semiconductor layer ACT1 may be insulated from the first gate electrode G1 by the first gate insulating film 120.

The first source electrode SSD1a and the first drain electrode SSD1b may be disposed between the upper interlayer insulating film 200 and the planarization film 300 and may penetrate the upper interlayer insulating film 200 and the first gate insulating film 120 to contact the first semiconductor layer ACT1.

The first metal layer M1 may be disposed between the substrate 100 and the substrate buffer layer 110, and may block light incident on the first semiconductor layer ACT1 of the switching transistor ST. Although not shown, the first metal layer M1 may be connected to a voltage source supplying a constant voltage, or may be connected to the first gate electrode G1 of the switching transistor ST or one of the first source electrode SSD1a and the first drain electrode SSD1b.

The driving transistor DT may control the driving current supplied to the light-emitting element OLED, and may include a second gate electrode G2, a second semiconductor layer ACT2, a second source electrode DSD1a, a second drain electrode DSD1b, and a second metal layer M2.

The second gate electrode G2 may be disposed between the second gate insulating film 150 and the upper interlayer insulating film 200. The second semiconductor layer ACT2 may be disposed between the element buffer layer 140 and the second gate insulating film 150 and may include an oxide semiconductor material. The oxide semiconductor material may include, for example, any one of an IZO (InZnO)-based material, an IGO (InGaO)-based material, an ITO (InSnO)-based material, an IGZO (InGaZnO)-based material, an IGZTO (InGaZnSnO)-based material, a GZTO (GaZnSnO)-based material, a GZO (GaZnO)-based material, an ITZO (InSnZnO)-based material, and a FIZO (FeInZnO)-based material. The second semiconductor layer ACT2 may be insulated from the second gate electrode G2 by the second gate insulating film 150.

The second source electrode DSD1a and the second drain electrode DSD1b may be disposed between the upper interlayer insulating film 200 and the planarization film 300, and may penetrate the upper interlayer insulating film 200 and the second gate insulating film 150 to contact the second semiconductor layer ACT2.

The second metal layer M2 may be disposed between the lower interlayer insulating film 130 and the element buffer layer 140, and may block light incident on the second semiconductor layer ACT2 of the driving transistor DT. Although not shown, the second metal layer M2 may be connected to a voltage source supplying a constant voltage, or may be connected to the second gate electrode G2 of the driving transistor DT or one of the second source electrode DSD1a and the second drain electrode DSD1b.

The second metal layer M2 may be located in the same layer as the second electrode plate C1b of the storage capacitor Cst, and may include the same conductive material, for example, a metal such as aluminum (Al), chromium (Cr), copper (Cu), titanium (Ti), molybdenum (Mo), or tungsten (W).

The first intermediate electrode SD2a may electrically connect the light-emitting element OLED and the driving transistor DT in each subpixel SP. A driving current generated by the driving transistor DT may be applied to the first intermediate electrode SD2a.

In addition, as illustrated in FIG. 14, a third intermediate electrode SD2c may be disposed in the same layer as the first intermediate electrode SD2a and spaced apart therefrom, and the third intermediate electrode SD2c may serve as a data line DL for supplying a data voltage Vdata to the subpixel SP.

In addition, although not shown, another intermediate electrode (not shown) may be further disposed in the pixel area AP and spaced apart from the first intermediate electrode SD2a and the third intermediate electrode SD2c on the same layer. The high-level voltage VDD or the reference voltage Vref may be applied to such another intermediate electrode (not shown).

The second intermediate electrode SD2b may be disposed between the first and second planarization films 310 and 320 in the circuit area AS. A driving voltage supplied to the subpixel may be applied to the second intermediate electrode SD2b, and a low-level driving voltage VSS supplied to the second electrode E2 (cathode) of the light-emitting element OLED may be applied to the second intermediate electrode SD2b, for example.

A clock line (e.g., CL1) may be positioned on the insulating layer on which the source electrodes SSD1a and DSD1a and the drain electrodes SSD1b and DSD1b of the driving transistor DT and the switching transistor ST are positioned.

For example, as shown in FIG. 14, the clock line (e.g., CL1) is disposed between the upper interlayer insulating film 200 and the planarization film 300 and is located on the same layer on which the source electrode and the drain electrode of each of the driving transistor DT and the switching transistor ST are disposed, and may include a conductive material of the same material as the source electrode and the drain electrode of each of the driving transistor DT and the switching transistor ST.

An inverted clock line (e.g., IL1) may be located on a different layer from the clock line CL within the circuit area AS. That is, the inverted clock line IL may be located apart from the clock line CL in the thickness direction z.

Specifically, the inverted clock line (e.g., IL1) may be located on the insulating layer on which the first metal layer M1 of the switching transistor ST is located, the insulating layer on which the second metal layer M2 of the driving transistor DT is located, or the insulating layer on which an electrode plate of the storage capacitor Cst connected to the driving transistor DT is located.

For example, as illustrated in FIG. 14, the inverted clock line (e.g., IL1) may be disposed between the substrate 100 and the substrate buffer layer 110 and located in the same layer as the first metal layer M1 of the switching transistor ST, and may include a conductive material of the same material as the first metal layer M1.

The clock line (e.g., CL1) and the inverted clock line (e.g., IL1) may overlap the second intermediate electrode SD2b located in the circuit area AS, and the inverted clock line e.g., IL1, may overlap the clock line, e.g., CL1.

As described above, the display device according to one or more embodiments of the present disclosure includes the inverted clock line IL extending in the same direction as the clock line (e.g., CL1) below the clock line (e.g., CL1) in the circuit area AS, as illustrated in FIG. 14, and reduces the amount of coupling of the clock line (e.g., CL1) with the data line DL by offsetting the clock signal (e.g., CLK1) using the inverted clock signal (e.g., ICLK1), thereby minimizing or at least reducing signal interference of the clock line (e.g., CL1) with respect to the data line DL.

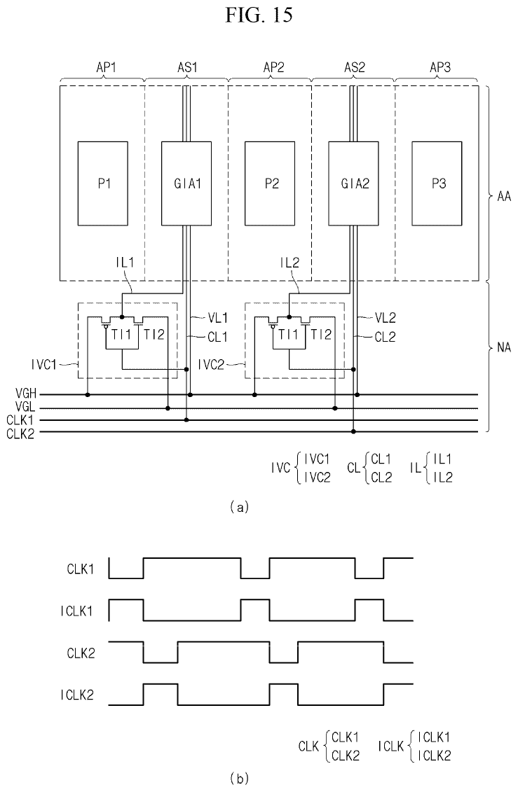

As illustrated in FIG. 15, the present disclosure can cancel a noise signal caused by the clock signal CLK by disposing the inverted clock line IL adjacent to the bottom of the clock line CL. Accordingly, the present disclosure can reduce coupling noise that may be caused by the clock line CL.

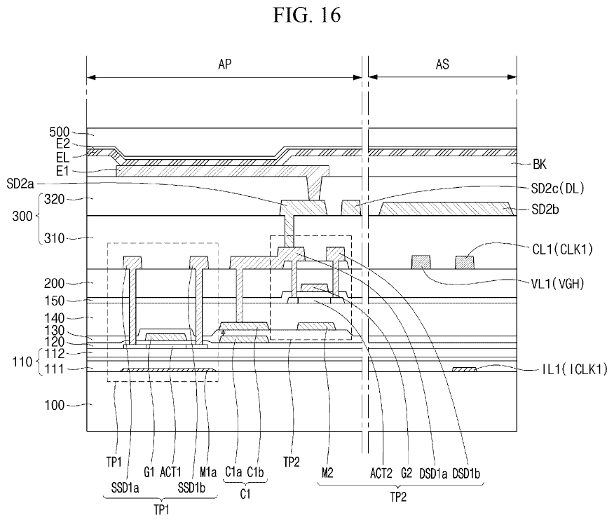

FIG. 15 is a diagram illustrating a second example of the structure in which the display panel has an inverter circuit according to the second embodiment of the present disclosure, and FIG. 16 shows an example illustrating a cross section of the display panel according to the second example of the second embodiment of the present disclosure illustrated in FIG. 15.

As illustrated in FIG. 15, in the second example of the structure in which the display panel 10 includes the inverter circuit IVC according to the second embodiment, a constant voltage line VL to which a constant voltage is applied may be disposed on one side of the clock line CL, and the inverted clock line IL may be disposed on the other side of the clock line CL or on the upper or lower side adjacent in the thickness direction z.

The gate high voltage or the gate low voltage may be applied to the constant voltage line VL. FIG. 15 illustrates an example in which the gate high voltage VGH is applied to a first constant voltage line VL1 of the first inverter circuit IVC1, and the gate low voltage VGL is applied to a second constant voltage line VL2 of the second inverter circuit IVC2.

As shown in FIG. 15, when the constant voltage line VL is disposed on one side of the clock line CL and the inverted clock line IL is disposed on the other side, above or below the clock line CL, signal interference on one side of the clock line CL is shielded by the constant voltage line VL, and signal interference on the other side of the clock line CL is shielded by the inverted clock line IL, and thus a noise signal caused by the clock line CL can be canceled and noise coupling due to the clock line CL can be reduced.

When the constant voltage line VL is disposed on one side of the clock line CL, the constant voltage line VL may be disposed on the same layer as the clock line CL. Specifically, the constant voltage line VL may be positioned on the insulating layer on which the source electrodes SSD1a and DSD1a and the drain electrodes SSD1b and DSD1b of the driving transistor DT and the switching transistor ST are positioned, apart from the clock line CL in the horizontal direction.

For example, as shown in FIG. 16, the constant voltage line (e.g., VL1) may be disposed between the upper interlayer insulating film 200 and the planarization film 300 and positioned on the same layer as the source electrodes and drain electrodes of the driving transistor DT and the switching transistor ST, and may include the same conductive material as the source electrodes and drain electrodes of the driving transistor DT and the switching transistor ST.

When the constant voltage line VL is disposed on one side of the clock line CL, the constant voltage line VL may be positioned between the clock line CL and the third intermediate electrode SD2c serving as a data line DL. Accordingly, signal interference of the clock line CL with respect to the data line DL can be more effectively reduced.

The inverted clock line (e.g., IL1) may be disposed to be spaced apart from the clock line (e.g., CL1) in the thickness direction z, as illustrated in FIG. 16. The constant voltage line (e.g., VL1), the clock line (e.g., CL1), and the inverted clock line (e.g., IL1) may be positioned in the circuit area AS and overlap the second intermediate electrode SD2b, and the inverted clock line (e.g., IL1) may overlap the clock line (e.g., CL1). Since the inverted clock line (e.g., IL1) has been described in detail in FIG. 14, description thereof is omitted.

Although a case in which the inverted clock line IL is spaced apart from the clock line CL in the thickness direction z has been described as an example, the present disclosure is not limited thereto. For example, the inverted clock line IL may also be spaced apart from the clock line CL in the horizontal direction x. This will be described below.

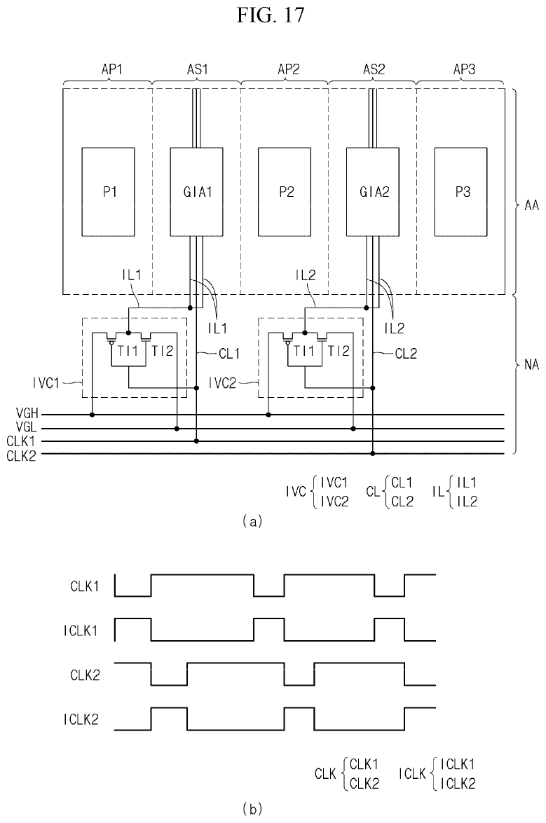

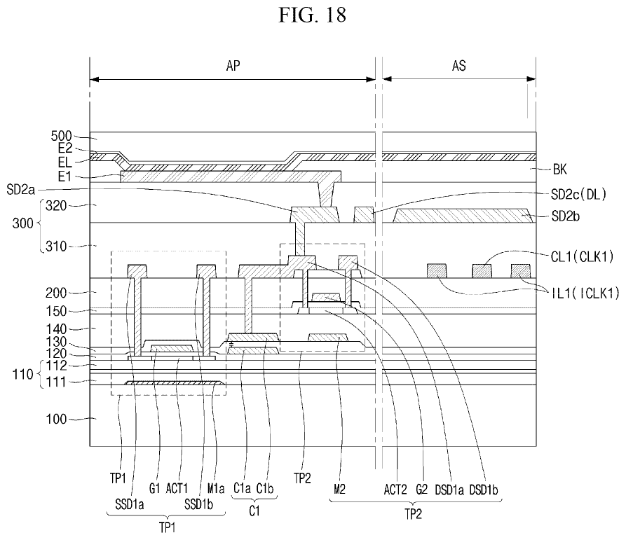

FIG. 17 is a diagram illustrating a third example of the structure in which the display panel includes an inverter circuit according to the second embodiment of the present disclosure, and FIG. 18 shows an example illustrating a cross section of the display panel according to the third example of the second embodiment of the present disclosure illustrated in FIG. 17.

In the third example of the structure in which the display panel 10 include the inverter circuit IVC according to the second embodiment of the present disclosure, the inverted clock line IL may be positioned on both sides of the clock line CL and spaced apart therefrom, as illustrated in FIG. 17.

As illustrated in FIG. 17, when the inverted clock line IL is positioned on and spaced apart from both sides of the clock line CL, a noise signal caused by the clock line CL due to the clock signal CLK applied to the clock line CL can be more reliably canceled. As shown in FIG. 17, when the inverted clock line IL is positioned on and spaced apart from both sides of the clock line CL, the inverted clock line IL may be positioned on the same layer as the clock line CL and spaced apart from the clock line CL within the circuit areas AS1 and AS2.

For example, as shown in FIG. 18, when the clock line CL is disposed between the upper interlayer insulating film 200 and the planarization film 300, like the source electrodes SSD1a and DSD1a and the drain electrodes SSD1b and DSD1b of the driving transistor DT and the switching transistor ST, the inverted clock line IL may also be disposed between the upper interlayer insulating film 200 and the planarization film 300, like the source electrodes and drain electrodes of the driving transistor DT and the switching transistor ST, and spaced apart from the clock line CL.

As shown in FIG. 18, the clock line (e.g., CL1) and the inverted clock lines (e.g., IL1) on both sides thereof may overlap the second intermediate electrode SD2b located in the circuit area AS.

In this manner, the display device according to one or more embodiments of the present disclosure includes a clock line (e.g., CL1) extending along a circuit area AS and inverted clock lines IL extending in the same direction adjacent thereto, and minimizes or at least reduces signal interference of the clock line (e.g., CL1) with respect to the data line DL by offsetting the clock signal (e.g., CLK1) of the clock line (e.g., CL1) using the inverted clock signal (e.g., ICLK1) of the inverted clock line (e.g., IL1).

The line width of the inverted clock line (e.g., IL1) may be optimally designed for cancelling coupling between the clock signal (e.g., CLK1) applied to the clock line (e.g., CL1) and the third intermediate electrode SD2c serving as the data line DL.

For example, the line width of the inverted clock line (e.g., IL1) is illustrated as being the same as the line width of the clock line (e.g., CL1) in FIG. 18, but the present disclosure is not limited thereto.

If the line width of the inverted clock line (e.g., IL1) is the same as that of the clock line (e.g., CL1), the amount of coupling between the inverted clock line (e.g., IL1) and the data line DL is greater than the amount of coupling between the clock line (e.g., CL1) and the data line DL, and thus the data voltage of the data line DL may be reversed.

Considering this, if the inverted clock line (e.g., IL1) is disposed on both sides of the clock line (e.g., CL1), for example, as shown in FIG. 18, the line width of the inverted clock line (e.g., IL1) may be designed to be less than the line width of the clock line (e.g., CL1) in consideration of the resistance of the line, parasitic capacitance, etc.

In addition, the display device according to one or more embodiments of the present disclosure can improve the arrangement structure of data lines of a pixel area AP located adjacent to a clock line CL of a circuit area (AS) to reduce coupling that may occur between a data line and the clock line CL, and prevent deterioration of the image quality of the display panel 10.

The display device according to one or more embodiments of the present disclosure has an inverted clock line extending in the same direction as a clock line extending along a circuit area adjacent thereto and offsets a clock signal of the clock line using an inverted clock signal of the inverted clock line, thereby minimizing or at least reducing signal interference caused by the clock line disposed in the circuit area.

The display device according to one or more embodiments of the present disclosure can reduce coupling that may occur between a data line and a clock line by improving the arrangement structure of data lines in the pixel area positioned adjacent to the clock line of the circuit area, thereby preventing deterioration of the image quality of the display panel.

It will be apparent to those skilled in the art that various modifications and variations can be made in the present disclosure without departing from the spirit or scope of the present disclosure. Thus, it is intended that the present disclosure cover the modifications and variations of the present disclosure provided they come within the scope of the appended claims and their equivalents.

What is claimed is:

1. A display device, comprising:
a display panel having an active area and a non-active area, and the display panel including:
a plurality of pixel areas located within the active area and in which a plurality of subpixels are positioned, and
a plurality of circuit areas alternately disposed with the plurality of pixel areas within the active area and in which scan circuits supplying scan signals to the plurality of subpixels are located;
an inverter circuit located in the non-active area, the inverter circuit configured to receive a clock signal supplied to the scan circuits, invert the received clock signal, and output an inverted clock signal;
a clock line to which the clock signal is applied, the clock line extending along the plurality of circuit areas and connected to the scan circuits; and
an inverted clock line to which the inverted clock signal is applied, the inverted clock line extending along the plurality of circuit areas from the inverter circuit,
wherein the inverted clock line is adjacent to the clock line and extends in a same direction as the clock line.

2. The display device of claim 1, wherein the inverter circuit includes a first inverter transistor and a second inverter transistor,
wherein the first inverter transistor includes a gate electrode connected to the clock line, a first electrode to which a gate high voltage is applied, and a second electrode connected to the inverted clock line,
wherein the second inverter transistor includes a gate electrode connected to the clock line, a first electrode to which a gate low voltage is applied, and a second electrode connected to the inverted clock line, and
wherein the first inverter transistor is a PMOS transistor and the second inverter transistor is an NMOS transistor.

3. The display device of claim 1, wherein the inverter circuit receives the clock signal having a gate high voltage and outputs the inverted clock signal having a gate low voltage, and
wherein the inverter circuit receives the clock signal having the gate low voltage and outputs the inverted clock signal having the gate high voltage.

4. The display device of claim 1, wherein each of the plurality of subpixels comprises:
a driving transistor located in a pixel area of the plurality of pixel areas and electrically connected to a light-emitting element; and
a switching transistor located in the pixel area and connected to the driving transistor,
wherein the clock line is located on an insulating layer on which a source electrode of each of the driving transistor and the switching transistor and a drain electrode of each of the driving transistor and the switching transistor are located.

5. The display device of claim 1, wherein the inverted clock line extends parallel to the clock line while maintaining a predetermined distance from the clock line.

6. The display device of claim 1, wherein the inverted clock line is located on a different layer from a layer on which the clock line is located within a circuit area of the plurality of circuit areas.

7. The display device of claim 4, wherein the inverted clock line is located on an insulating layer on which a metal layer is positioned, the metal layer positioned below and overlapped with a semiconductor layer of the driving transistor, or
wherein the inverted clock line is located on an insulating layer on which a metal layer is positioned, the metal layer positioned below and overlapped with a semiconductor layer of the switching transistor, or
wherein the inverted clock line is located on an insulating layer on which an electrode plate of a storage capacitor connected to the driving transistor is positioned.

8. The display device of claim 1, wherein the inverted clock line and the clock line are positioned on a same layer within a circuit area of the plurality of circuit areas and spaced apart from each other.

9. The display device of claim 4, wherein the inverted clock line and the clock line are spaced apart from each other on the insulating layer.

10. The display device of claim 1, wherein the inverted clock line is positioned on and spaced apart from both sides of the clock line.

11. The display device of claim 1, wherein the plurality of circuit areas includes a first circuit area and a second circuit area,
wherein the plurality of pixel areas includes a first pixel area and a second pixel area alternately positioned with the first circuit area and the second circuit area,
wherein each of the first pixel area and the second pixel area includes a first subpixel area, a second subpixel area and a third subpixel area sequentially arranged in a direction away from each of the first circuit area and the second circuit area,
wherein a first subpixel, a second subpixel and a third subpixel are disposed in the first subpixel area, the second subpixel area and the third subpixel area, respectively,
wherein a first data line, a second data line and a third data line are connected to the first subpixel, the second subpixel and the third subpixel, respectively, and
wherein the first data line, the second data line and the third data line are disposed in the first subpixel area, the second subpixel area and the third subpixel area, respectively.

12. The display device of claim 11, wherein a plurality of constant voltage lines are disposed at both edges of each of the first circuit area and the second circuit area, and wherein the clock line is disposed between the plurality of constant voltage lines.

13. The display device of claim 11, wherein the first data line disposed in the first subpixel area of each of the first pixel area and the second pixel area is positioned on a first side of the first subpixel farther away from the first circuit area and the second circuit area, and
wherein the third data line disposed in the third subpixel area of each of the first pixel area and the second pixel area is positioned on a second side of the third subpixel farther away from the first circuit area and the second circuit area.

14. The display device of claim 11, wherein the first data line, the second data line, and the third data line of the first pixel area and the first data line, the second data line, and the third data line of the second pixel area are disposed symmetrically with respect to the second circuit area.

15. The display device of claim 11, further comprising a multiplexer circuit located in the non-active area adjacent to the first pixel area and the second pixel area, the multiplexer circuit receiving a data signal from a data driver, and the multiplexer circuit sequentially outputting a data voltage to the first data line of the first pixel area and the first data line of the second pixel area.

16. The display device of claim 15, wherein the multiplexer circuit comprises:
a first multiplex transistor having a gate electrode to which a first multiplex signal is applied, a first electrode connected to a data channel of the data driver, and a second electrode connected to the first subpixel located in the first pixel area through the first data line; and
a second multiplex transistor having a gate electrode to which a second multiplex signal is applied, a first electrode connected to the data channel, and a second electrode connected to the second subpixel located in the second pixel area through the second data line.

17. The display device of claim 16, wherein the data signal that is input to the data channel includes a first data signal applied to the first subpixel through the first data line of the first pixel area and a second data signal applied to the second subpixel through the second data line of the second pixel area.

18. The display device of claim 17, wherein the first data signal is output to the first data line of the first pixel area when the first multiplex signal has a turn-on voltage, and wherein the second data signal is output to the second data line of the second pixel area when the second multiplex signal has the turn-on voltage.

19. The display device of claim 4, wherein the inverted clock line is located on the insulating layer and on two sides of and spaced apart from the clock line, and wherein a line width of the inverted clock line is equivalent to or smaller than a line width of the clock line.

20. The display device of claim 12, wherein the plurality of constant voltage lines extend in a same manner as the clock line.
